(19) United States
(12) Patent Application Publication
(10) Pub. No.: US 2018/0239205 A1
(43) Pub. Date: Aug. 23, 2018

(54) ELECTROOPTICAL DEVICE, MANUFACTURING METHOD OF ELETROOPTICAL DEVICE, AND ELECTRONIC APPARATUS

(71) Applicant: SEIKO EPSON CORPORATION, Tokyo (JP)

(72) Inventor: Tomoki YOKOTA, Suwa-shi (JP)

(73) Assignee: SEIKO EPSON CORPORATION, Tokyo (JP)

(21) Appl. No.: 15/899,396

(22) Filed: Feb. 20, 2018

(30) Foreign Application Priority Data
Feb. 23, 2017 (JP) 2017-031825

(51) Int. Cl. G02F 1/1362; G02F 1/1343; G02F 1/1368; G02F 1/1337; G09F 9/30; H01L 27/105; H01L 21/822; H01L 29/786

(52) U.S. Cl. CPC G02F 1/136213; G02F 1/134363; G02F 1/13439; G02F 1/136209; G02F 1/136286; H01L 29/786; G02F 1/133707; G09F 9/30; H01L 27/105; H01L 21/822; G02F 1/1368

(57) ABSTRACT

Liquid crystal device includes insulating layer disposed on substrate, a groove provided on insulating layer for each pixel, and capacitor provided on groove. Capacitor includes first capacitor electrode that includes recess-shaped and flange portions extending outside recess-shaped portion from upper end of recess-shaped portion along planar direction, insulator that includes first portion disposed in recess-shaped portion and second portion protruding in projection shape from upper end of recess-shaped portion along thickness direction, second capacitor electrode that is disposed so as to cover second portion of insulator and to overlap with first capacitor electrode in plan view and is connected to flange portion, capacitor insulating film that covers outer surface of second capacitor electrode and outer surface of a portion of first capacitor electrode, and third capacitor electrode that covers second capacitor electrode and portion of first capacitor electrode by interposing capacitor insulating film.

### BACKGROUND

### 1. Technical Field

The present invention relates to an electrooptical device, a manufacturing method of an electrooptical device, and an electronic apparatus.

### 2. Related Art

As an electrooptical device, a liquid crystal device in which a liquid crystal layer is interposed between an element substrate on which a switching element is disposed for each pixel and a counter substrate, has been known. In the liquid crystal device, a capacitor functioning as a storage capacitor that holds a potential which is written in the pixel based on an image signal is included for each pixel. When a holding capacitance of the capacitor is small, it is difficult to sufficiently hold the potential written in the pixel, and this causes a problem such as display unevenness. For this reason, it is necessary that the capacitor has a sufficient holding capacitance.

In addition, in the liquid crystal device used as a liquid crystal light valve, when intense light from a light source is incident on a semiconductor layer constituting a switching element, a leakage current occurs due to the light, and this causes flicker and pixel unevenness on a display image. For this reason, as a light shielding structure, for example, a configuration in which a light shielding layer shields light incident from above and below the semiconductor layer, is used.

The capacitor is configured with, for example, a pair of capacitor electrodes with a light shielding property that are disposed so as to be opposite to each other with a dielectric layer interposed therebetween. As an area of the capacitor electrode becomes larger, the holding capacitance of the capacitor becomes larger. However, when the area of the capacitor electrode is increased, an aperture ratio of the pixel is decreased. For this reason, a configuration in which the total area of the capacitor electrodes is increased while decreasing an area of each capacitor electrode in plan view (hereinafter, referred to as a planar area) by forming the capacitor electrodes so as to cover an upper surface and side surfaces of a projection-shaped portion provided on the substrate, has been proposed (for example, refer to JP-A-2015-94880).

However, in order to realize high-resolution display, when the number of pixels is increased and a pixel arrangement pitch is decreased, the aperture ratio of the pixel relatively decreases. When a light shielding region is decreased in order to increase the aperture ratio, a region in which the projection-shaped portion forming the capacitor electrode can be provided also decreases, and as a result it is difficult to secure a sufficient holding capacitance. In other words, it is difficult to realize a high aperture ratio and secure a sufficient holding capacitance in response to an increase in the number of pixels and a decrease of the pitch in pixel arrangement. Therefore, it is necessary to realize a capacitor capable of further increasing the holding capacitance per unit planar area.

### SUMMARY

The invention can be realized in the following aspects or application examples.

### Application Example 1

According to this application example, there is provided an electrooptical device including: a substrate; an insulating layer disposed on the substrate; a groove provided on the insulating layer for each pixel; and a capacitor provided on the groove, in which the capacitor includes a first capacitor electrode that includes a recess-shaped portion disposed in the groove and a flange portion extending outside the recess-shaped portion from an upper end of the recess-shaped portion along a planar direction of the substrate, an insulator that includes a first portion disposed in the recess-shaped portion and a second portion protruding in a projection shape from the upper end of the recess-shaped portion along a thickness direction of the substrate, a second capacitor electrode that is disposed so as to cover the second portion of the insulator and to overlap with the first capacitor electrode in plan view and is connected to the flange portion, a capacitor insulating film that covers an outer surface of the second capacitor electrode and an outer surface of a portion of the first capacitor electrode including the flange portion, and a third capacitor electrode that covers the second capacitor electrode and the portion of the first capacitor electrode including the flange portion by interposing the capacitor insulating film.

With the configuration according to this application example, in the capacitor, the first capacitor electrode and the second capacitor electrode function as a lower electrode disposed on the substrate, and the third capacitor electrode functions as an upper electrode disposed on the lower electrode above the substrate. The capacitance of the capacitor is determined based on an area in which the lower electrode and the upper electrode are opposite to each other with the capacitor insulating film interposed therebetween. Similar to the first capacitor electrode described in JP-A-2015-94880, the second capacitor electrode of the lower electrode covers an upper surface and side surfaces of the second portion of the insulator that protrudes in a projection shape, and is opposite to the third capacitor electrode as the upper electrode. A portion of the first capacitor electrode of the lower electrode that includes the flange portion connected to the second capacitor electrode, is opposite to the third capacitor electrode. That is, an area of the lower electrode opposite to the upper electrode of the capacitor according to this application example is larger than that in the configuration described in JP-A-2015-94880, by an area of the portion of the first capacitor electrode that includes the flange portion. On the other hand, since the second capacitor electrode is disposed so as to overlap with the first capacitor electrode in plan view, even when the total area in which the lower electrode and the upper electrode are opposite to each other is increased by addition of the portion of the first capacitor electrode, a planar area of the capacitor does not change. Thereby, as compared with the configuration described in JP-A-2015-94880, it is possible to increase a holding capacitance per unit planar area of the capacitor. Therefore, it is possible to realize a high aperture ratio of the electrooptical device and secure a holding capacitance of the electrooptical device.

### Application Example 2

In the electrooptical device according to the application example, preferably, the second portion of the insulator overlaps with a portion of the flange portion of the first capacitor electrode in plan view.

With the configuration according to this application example, the second portion of the insulator overlaps with the flange portion of the first capacitor electrode in plan view. Thus, as compared with a case where the second portion of the insulator does not overlap with the flange portion of the first capacitor electrode in plan view, a length of the flange portion, which overlaps with the second capacitor electrode covering the second portion in plan view, becomes longer. Therefore, the total area in which the lower electrode and the upper electrode are opposite to each other becomes larger than the planar area of the lower electrode, and thus it is possible to further increase the holding capacitance per unit planar area of the capacitor. In addition, it is possible to control the length of the flange portion by adjusting a length with which the second portion of the insulator overlaps with the flange portion of the first capacitor electrode in plan view.

### Application Example 3

In the electrooptical device according to the application example, preferably, the insulator includes a recess portion which is recessed from the second portion to the first portion, and the second capacitor electrode is also disposed in the recess portion of the insulator.

With the configuration according to this application example, the second capacitor electrode is disposed so as to cover a bottom surface and inner surfaces of the recess portion which is recessed from the second portion to the first portion of the insulator. Thus, the planar area of the second capacitor electrode increases by an area corresponding to the bottom surface of the recess portion of the insulator, while the total area of the second capacitor electrode increases by an area corresponding to the bottom surface and the inner surfaces of the recess portion of the insulator. Similarly, the total area of the third capacitor electrode, which covers the second capacitor electrode by interposing the capacitor insulating film, also increases. Thereby, it possible to further increase the holding capacitance per unit planar area of the capacitor.

### Application Example 4

In the electrooptical device according to the application example, preferably, the recess-shaped portion includes a bottom portion disposed in the groove and a portion on the upper end side that is disposed above the insulating layer, and the portion of the first capacitor electrode includes the portion on the upper end side of the recess-shaped portion and the flange portion.

With the configuration according to this application example, the third capacitor electrode is also disposed to be opposite to the portion of the recess-shaped portion that is positioned above the insulating layer in addition to the flange portion of the first capacitor electrode. The recess-shaped portion of the first capacitor electrode is inside the flange portion in plan view, and thus it is possible to increase the total area in which the lower electrode and the upper electrode are opposite to each other, without increasing the planar area of the capacitor.

### Application Example 5

Preferably, the electrooptical device according to the application example further includes an electrode that is disposed between the substrate and the capacitor and is brought into contact with the bottom portion of the recess-shaped portion.

With the configuration according to this application example, the electrode provided between the substrate and the capacitor is brought into contact with the bottom portion of the recess-shaped portion of the first capacitor electrode, and thus it is possible to use the electrode as a relay electrode for relaying an electrical connection to the first capacitor electrode disposed in the groove of the insulating layer.

### Application Example 6

Preferably, the electrooptical device according to the application example further includes a switching element disposed between the substrate and the capacitor and a light shielding layer disposed between the substrate and the switching element so as to overlap with the switching element in plan view, and the capacitor is disposed so as to overlap with the light shielding layer in plan view.

With the configuration according to this application example, the capacitor is disposed so as to overlap with the light shielding layer in plan view, and thus the aperture ratio of the pixel is not reduced. In addition, the light shielding layer is disposed below the switching element on the substrate, and the capacitor is disposed above the switching element on the substrate. Thus, the capacitor can contribute to shielding of light from above the switching element.

### Application Example 7

In the electrooptical device according to the application example, preferably, the capacitor includes an intersection portion in which a portion extending along a first direction of the planar direction and a portion extending along a second direction of the planar direction that intersects with the first direction are connected to each other.

With the configuration according to this application example, even in a case where a ratio of a depth of the groove with respect to a width of the groove is large, in other words, a ratio of a height of the capacitor with respect to a width of the capacitor is large and as a result there is a concern that a mechanical strength of the capacitor is reduced, by providing the intersection portion in which the portion extending along the first direction and the portion extending along the second direction are connected to each other, it is possible to suppress a reduction in the mechanical strength of the capacitor.

### Application Example 8

According to this application example, there is provided an electronic apparatus including the electrooptical device according to the application example.

With the configuration according to this application example, the electrooptical device capable of realizing the high aperture ratio and securing the holding capacitance is provided, and thus it is possible to provide the electronic apparatus with high brightness and a stable display quality.

### Application Example 9

According to this application example, there is provided a manufacturing method of an electrooptical device, the method including: forming an insulating layer stack in an order of a first insulating layer, a second insulating layer, and a third insulating layer which is inferior to the second insulating layer in etching resistance on a substrate; forming a groove extending from the third insulating layer to the first insulating layer by anisotropic etching; forming a first capacitor electrode film which covers a front surface of the third insulating layer and includes a recess-shaped portion in the groove; forming a fourth insulating layer in the recess-shaped portion and on the first capacitor electrode film; forming an insulator that includes a first portion disposed in the recess-shaped portion and a second portion protruding in a projection shape from an upper end of the recess-shaped portion above the first capacitor electrode film, by removing a portion of the fourth insulating layer by anisotropic etching; forming a second capacitor electrode film so as to cover the second portion of the insulator and the first capacitor electrode film which is exposed in the insulator formation; forming a second capacitor electrode by removing the second capacitor electrode film by anisotropic etching except for a portion of the second capacitor electrode film that covers the second portion of the insulator and is brought into contact with the first capacitor electrode film; forming a first capacitor electrode by removing the first capacitor electrode film by anisotropic etching except for a portion of the first capacitor electrode film that overlaps with the second capacitor electrode in plan view; removing the third insulating layer by isotropic etching; forming a capacitor insulating film which covers an outer surface of the second capacitor electrode and an outer surface of a portion of the first capacitor electrode that is positioned above the second insulating layer; forming a third capacitor electrode film so as to cover the capacitor insulating film; and forming a third capacitor electrode by removing the third capacitor electrode film by anisotropic etching except for a portion of the third capacitor electrode film which covers the second capacitor electrode and the portion of the first capacitor electrode that is positioned above the second insulating layer by interposing the capacitor insulating film.

With the configuration according to this application example, by performing the processing from the insulating layer stack formation to the third capacitor electrode formation, it is possible to increase the holding capacitance per unit planar area of the capacitor. Thus, it is possible to manufacture the electrooptical device capable of realizing the high aperture ratio and securing the holding capacitance. In the insulator formation, by adjusting the width of the second portion of the insulator with respect to the width of the first portion disposed in the recess-shaped portion of the first capacitor electrode film, it is possible to control a planar size of the second capacitor electrode to be formed in the second capacitor electrode formation and a length of the flange portion of the first capacitor electrode to be formed in the first capacitor electrode formation. In the third insulating layer removal, since the second insulating layer functions as an etching stopper, the flange portion of the first capacitor electrode and the portion of the recess-shaped portion that is positioned above the second insulating layer are reliably exposed. Thus, it is possible to suppress excess etching. By adjusting a thickness of the third insulating layer formed on the second insulating layer in the insulating layer stack formation, it is possible to control a length of the portion of the first capacitor electrode that is exposed above the second insulating layer in the third insulating layer removal. In the capacitor insulating film formation and the third capacitor electrode film formation, the third capacitor electrode film is formed so as to cover the outer surface of the second capacitor electrode and the outer surface of the portion of the first capacitor electrode including the flange portion that is positioned above the second insulating layer by interposing the capacitor insulating film. Thus, as compared with the capacitor described in JP-A-2015-94880, it is possible to increase the total area in which the lower electrode and the upper electrode are opposite to each other, without increasing the planar area of the capacitor.

### BRIEF DESCRIPTION OF THE DRAWINGS

The invention will be described with reference to the accompanying drawings, wherein like numbers reference like elements.

FIG. 1 is a schematic plan view illustrating a configuration of a liquid crystal device according to a first embodiment.

FIG. 2 is a schematic sectional view taken along a line II-II of FIG. 1.

FIG. 3 is an equivalent circuit diagram illustrating an electrical configuration of the liquid crystal device according to the first embodiment.

FIG. 4 is a schematic plan view illustrating an arrangement of pixels of the liquid crystal device according to the first embodiment.

FIG. 5 is a schematic plan view illustrating a configuration of the pixel of the liquid crystal device according to the first embodiment.

FIG. 6 is a schematic sectional view taken along a line VI-VI of FIG. 5.

FIG. 7 is a schematic sectional view illustrating a structure of a capacitor according to the first embodiment.

FIG. 8 is a flowchart illustrating a forming method of the capacitor according to the first embodiment.

FIG. 9 is a schematic sectional view explaining the forming method of the capacitor according to the first embodiment.

FIG. 10 is a schematic sectional view explaining the forming method of the capacitor according to the first embodiment.

FIG. 11 is a schematic sectional view explaining the forming method of the capacitor according to the first embodiment.

FIG. 12 is a schematic sectional view explaining the forming method of the capacitor according to the first embodiment.

FIG. 13 is a schematic sectional view explaining the forming method of the capacitor according to the first embodiment.

FIG. 14 is a schematic sectional view explaining the forming method of the capacitor according to the first embodiment.

FIG. 15 is a schematic sectional view explaining the forming method of the capacitor according to the first embodiment.

FIG. 16 is a schematic sectional view explaining the forming method of the capacitor according to the first embodiment.

FIG. 17 is a schematic sectional view explaining the forming method of the capacitor according to the first embodiment.

FIG. 18 is a schematic sectional view explaining the forming method of the capacitor according to the first embodiment.

FIG. 19 is a schematic sectional view explaining the forming method of the capacitor according to the first embodiment.

FIG. 20 is a schematic sectional view explaining the forming method of the capacitor according to the first embodiment.

FIG. 21 is a schematic sectional view explaining the forming method of the capacitor according to the first embodiment.

FIG. 22 is a schematic sectional view illustrating a structure of the capacitor according to a second embodiment.

FIG. 23 is a schematic sectional view explaining the forming method of the capacitor according to the second embodiment.

FIG. 24 is a schematic sectional view explaining the forming method of the capacitor according to the second embodiment.

FIG. 25 is a schematic sectional view explaining the forming method of the capacitor according to the second embodiment.

FIG. 26 is a schematic sectional view explaining the forming method of the capacitor according to the second embodiment.

FIG. 27 is a schematic sectional view illustrating a structure of the capacitor according to a third embodiment.

FIG. 28 is a schematic plan view illustrating a planar shape of the capacitor according to the third embodiment.

FIG. 29 is a schematic plan view illustrating a planar shape of the capacitor according to the third embodiment.

FIG. 30 is a schematic diagram illustrating a configuration of a projector as an electronic apparatus according to a fourth embodiment.

FIG. 31 is a schematic sectional view illustrating a structure of the capacitor according to a modification example 1.

### DESCRIPTION OF EXEMPLARY EMBODIMENTS

Hereinafter, embodiments according to the invention will be described with reference to the drawings. The drawings used for description are illustrated by being enlarged, reduced, or exaggerated as appropriate such that a portion to be explained can be recognized. In addition, portions other than components necessary for the description may be omitted in the drawings.

In the following embodiments, for example, a case where a component is disposed “on a substrate” includes a case where a component is disposed so as to be brought into contact with a substrate, a case where a component is disposed on a substrate via another component, or a case where a portion of a component is disposed on a substrate via another component.

### First Embodiment

### Electrooptical Device

Here, as an example of an electrooptical device, an active matrix type liquid crystal device including a thin film transistor (TFT) as a switching element of a pixel will be described. The liquid crystal device may be appropriately used as, for example, a light modulation element (liquid crystal light valve) of a projection type display apparatus (projector) to be described.

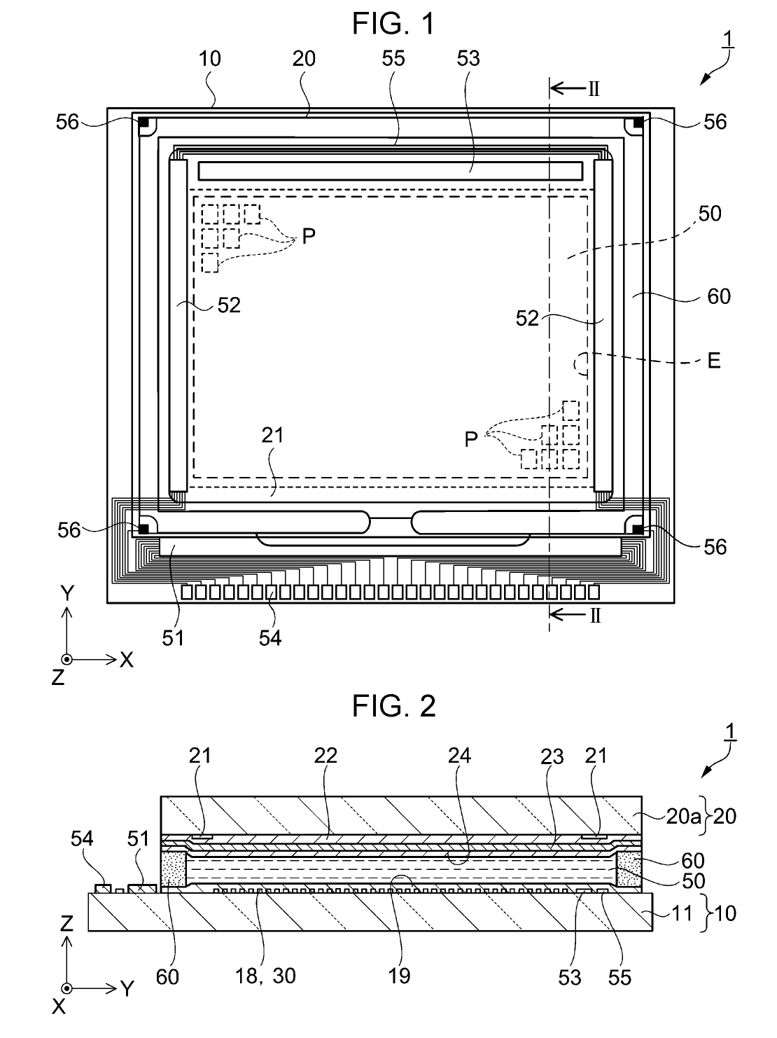

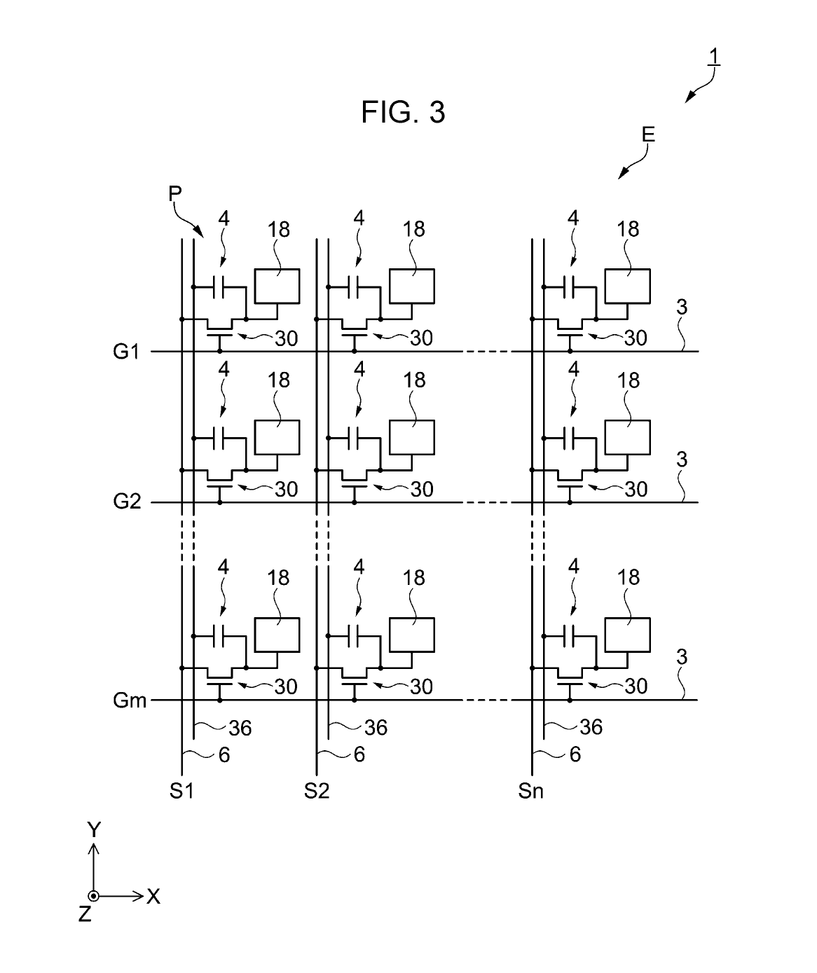

First, the liquid crystal device as the electrooptical device according to a first embodiment will be described with reference to FIGS. 1, 2, and 3. FIG. 1 is a schematic plan view illustrating a configuration of the liquid crystal device according to the first embodiment. FIG. 2 is a schematic sectional view taken along a line II-II of FIG. 1. In addition, FIG. 3 is an equivalent circuit diagram illustrating an electrical configuration of the liquid crystal device according to the first embodiment.

FIGS. 1 and 2, the liquid crystal device 1 according to the first embodiment includes an element substrate 10, a counter substrate 20 disposed so as to be opposite to the element substrate 10, and an electrooptical material layer (liquid crystal layer) 50 disposed between the element substrate 10 and the counter substrate 20. As a substrate 11 constituting the element substrate 10 and a substrate 20a constituting the counter substrate 20, for example, a substrate made of a light transmitting material such as glass or quartz is used.

The element substrate 10 is slightly larger than the counter substrate 20, and both substrates are joined to each other via a sealing member 60 disposed in a frame shape. The liquid crystal layer 50 is configured with a liquid crystal having positive or negative dielectric anisotropy as an electrooptical material, which is sealed in a space surrounded by the element substrate 10, the counter substrate 20, and the sealing member 60.

The sealing member 60 is made of, for example, an adhesive such as a thermosetting epoxy resin or a ultraviolet-curable epoxy resin. In the sealing member 60, a spacer (not illustrated) for maintaining a constant gap between the element substrate 10 and the counter substrate 20 is mixed. A frame-shaped light shielding layer 21 disposed on the counter substrate 20 is disposed inside the sealing member 60 disposed in a frame shape. The light shielding layer 21 is made of, for example, a metal or a metal oxide having a light shielding property.

The inside of the light shielding layer 21 is a display region E in which a plurality of pixels P are arranged. The display region E is a region in which display is substantially performed in the liquid crystal device 1. Although not illustrated in FIG. 1 and FIG. 2, even in the display region E, light shielding portions for partitioning the plurality of pixels P in plan are arranged, for example, in a lattice pattern.

A data line driving circuit 51 and a plurality of external connection terminals 54 are disposed outside the sealing member 60 on one side portion of the element substrate 10 along the one side portion. In addition, an inspection circuit 53 is disposed inside the sealing member 60 along another one side portion of the element substrate 10 that is opposite to the one side portion. Further, scanning line driving circuits 52 are disposed inside the sealing member 60 along the other two side portions of the element substrate 10 that are perpendicular to the two side portions and are opposite to each other.

A plurality of wirings 55 which connect the two scanning line driving circuits 52 to each other are disposed inside the sealing member 60 on one side portion at which the inspection circuit 53 is disposed. The wirings connected to the data line driving circuit 51 and the scanning line driving circuits 52 are connected to the plurality of external connection terminals 54. In addition, vertical conduction portions 56 for an electrical conduction between the element substrate 10 and the counter substrate 20 are disposed at corner portions of the counter substrate 20. The arrangement of the inspection circuit 53 is not limited thereto, and the inspection circuit 53 may be provided at a position along an inner side of the sealing member 60 between the data line driving circuit 51 and the display region E.

In the following description, it is assumed that a direction along the one side portion at which the data line driving circuit 51 is disposed is an X direction as a first direction, and that a direction along the other two side portions which are perpendicular to the one side portion and are opposite to each other is a Y direction as a second direction. A direction taken along a line II-II of FIG. 1 is a direction along the Y direction. In addition, it is assumed that a direction which is perpendicular to the X direction and the Y direction and is directed toward the upside of FIG. 2 is a Z direction. In this specification, a view when the liquid crystal device 1 is viewed from a normal direction (Z direction) of a front surface of the counter substrate 20 is referred to as “plan view”.

As illustrated in FIG. 2, a TFT 30 (refer to FIG. 3) as a switching element disposed for each pixel P, a pixel electrode 18 which transmits light, a signal wiring (not illustrated), and an alignment film 19 which covers the pixel electrode 18 are disposed on the liquid crystal layer 50 of the element substrate 10. The pixel electrode 18 is made of a conductive film such as indium tin oxide (ITO) or indium zinc oxide (IZO) that transmits light.

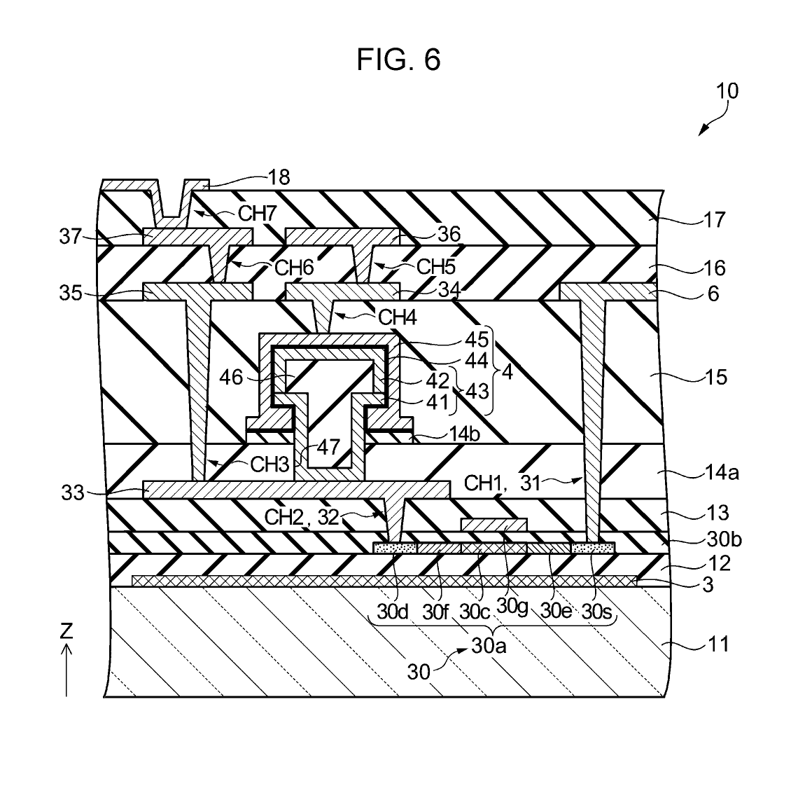

A light shielding structure is applied to the element substrate 10 according to the present embodiment, the light shielding structure for preventing an unstable switching operation of the TFT 30 due to light which is incident on a semiconductor layer 30a (refer to FIG. 6) of the TFT 30.

The light shielding layer 21, an interlayer 22, a common electrode 23, and an alignment film 24 which covers the common electrode 23 are disposed on the liquid crystal layer 50 of the counter substrate 20.

As illustrated in FIGS. 1 and 2, the light shielding layer 21 is disposed in a frame shape at a position which is overlapped with the scanning line driving circuit 52, the plurality of wirings 55, and the inspection circuit 53 in plan view. The light shielding layer 21 prevents an erroneous operation of the peripheral circuits including the driving circuits due to light by shielding the light incident from the counter substrate 20. In addition, unnecessary stray light is shielded so as not to be incident on the display region E, and thus it is possible to secure high contrast in display of the display region E.

The interlayer 22 illustrated in FIG. 2 is formed so as to cover the light shielding layer 21. The interlayer 22 is formed of an insulating film such as silicon oxide (SiO₂), and transmits light. The interlayer 22 is disposed so as to relax unevenness caused by the light shielding layer 21 and flatten a surface of the liquid crystal layer 50 on which the common electrode 23 is formed. As a method of forming the interlayer 22, for example, a method of forming a film using a chemical vapor deposition (CVD) method or the like may be used.

The common electrode 23 is made of, for example, a conductive film such as indium tin oxide (ITO) or indium zinc oxide (IZO) that transmits light. The common electrode 23 is disposed so as to cover the interlayer 22, and is electrically connected to the wirings on the element substrate 10 by the vertical conduction portions 56 disposed at the four corners of the counter substrate 20 as illustrated in FIG. 1.

The alignment film 19 and the alignment film 24 are selected based on an optical design of the liquid crystal device 1. For example, the alignment film 19 and the alignment film 24 may be formed by forming a film using an organic material such as polyimide and performing an alignment treatment substantially horizontally on liquid crystal molecules to rub a front surface of the film, or may be formed by forming a film using an inorganic material such as SiOx (silicon oxide) by a vapor deposition method and performing an alignment treatment substantially vertically on liquid crystal molecules.

The liquid crystal constituting the liquid crystal layer 50 modulates light so as to display a gradation by changing alignments and orders of molecular aggregations according to an applied voltage level. For example, in a case of a normally-white mode, transmittance of incident light decreases according to a voltage which is applied in units of pixels P. In a case of a normally-black mode, transmittance of incident light increases according to a voltage which is applied in units of pixels P, and light with contrast according to an image signal is emitted from the whole liquid crystal device 1.

As illustrated in FIG. 3, in the display region E, scanning lines 3 and data lines 6 are formed so as to be insulated from each other and intersect with each other. A direction in which the scanning lines 3 extend is the X direction as the first direction, and a direction in which the data lines 6 extend is the Y direction. The pixel P is disposed corresponding to an intersection between the scanning line 3 and the data line 6. In each pixel P, the pixel electrode 18 and the thin film transistor (TFT) 30 as a switching element are disposed.

A source electrode 31 (refer to FIG. 6) of the TFT 30 is electrically connected to the data line 6. The data lines 6 are connected to the data line driving circuit 51 (refer to FIG. 1), and supply image signals (data signals) S1, S2, . . . , Sn supplied from the data line driving circuit 51 to the pixels P. The image signals S1, S2, . . . , Sn supplied from the data line driving circuit 51 may be supplied to the data lines 6 line by line in this order, or may be supplied to the plurality of data lines 6 adjacent to each other for each group.

A gate electrode 30g (refer to FIG. 6) of the TFT 30 is electrically connected to the scanning line 3. The scanning lines 3 are connected to the scanning line driving circuit 52 (refer to FIG. 1), and supply scanning signals G1, G2, . . . , Gm supplied from the scanning line driving circuit 52 to each pixel P. The scanning line driving circuit 52 supplies the scanning signals G1, G2, . . . , Gm to the scanning lines 3 line by line according to a pulse at a predetermined timing. A drain electrode 32 (refer to FIG. 6) of the TFT 30 is electrically connected to the pixel electrode 18.

The image signals S1, S2, . . . , Sn are written on the pixel electrodes 18 at a predetermined timing via the data lines 6 by turning on the TFTs 30 for a certain period. The image signal with a predetermined level that is written on the liquid crystal layer 50 via the pixel electrode 18 in this manner is held for a certain period in a liquid crystal capacitor which is formed between the pixel electrode 18 and the common electrode 23 (refer to FIG. 2) disposed on the counter substrate 20.

When a voltage signal is applied to the liquid crystal of each pixel P, an alignment state of the liquid crystal changes according to the applied voltage level. Thereby, the light incident on the liquid crystal layer 50 (refer to FIG. 2) is modulated, and thus a gradation is displayed.

In order to prevent leakage of the image signals S1, S2, . . . , Sn held in the liquid crystal capacitor, a capacitor 4 functioning as a storage capacitor is disposed in parallel with the liquid crystal capacitor. The capacitor 4 is provided between a drain of the TFT 30 and a common potential line 36 functioning as a capacitor line.

The data lines 6 are connected to the inspection circuit 53 illustrated in FIG. 1. In manufacturing processes of the liquid crystal device 1, the inspection circuit 53 is configured so as to be able to confirm an operation defect and the like of the liquid crystal device 1 by detecting the image signal, and are not illustrated in the equivalent circuit of FIG. 3. In addition, the inspection circuit 53 may include a sampling circuit which samples the image signal and supplies the sampled signal to the data line 6, and a precharge circuit which supplies a precharge signal with a predetermined voltage level to the data line 6 prior to the image signal.

### Arrangement and Configuration of Pixel

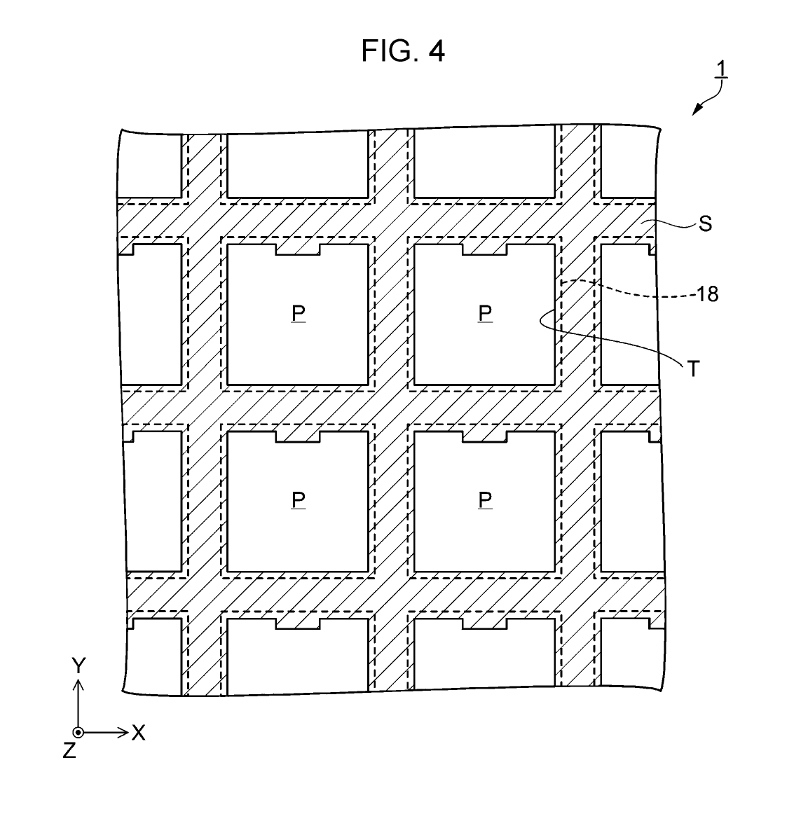

Next, a planar arrangement of the pixels P will be described with reference to FIG. 4. FIG. 4 is a schematic plan view illustrating an arrangement of the pixels of the liquid crystal device according to the first embodiment. As illustrated in FIG. 4, in the liquid crystal device 1, the pixel P includes an opening region T having a substantially rectangular shape. For each pixel P, the pixel electrode 18 having a substantially rectangular shape is disposed. The pixel electrode 18 is disposed so as to overlap with the opening region T in plan view, and is formed to be larger than the opening region T.

The opening region T is surrounded by a light shielding region S which shields light. The light shielding region S is disposed in a lattice pattern extending along the X direction and the Y direction. An outer edge portion of the pixel electrode 18 overlaps with the light shielding region S in plan view. The scanning lines 3 (refer to FIG. 3) extending along the X direction and the data lines 6 (refer to FIG. 3) extending along the Y direction are disposed in the light shielding region S.

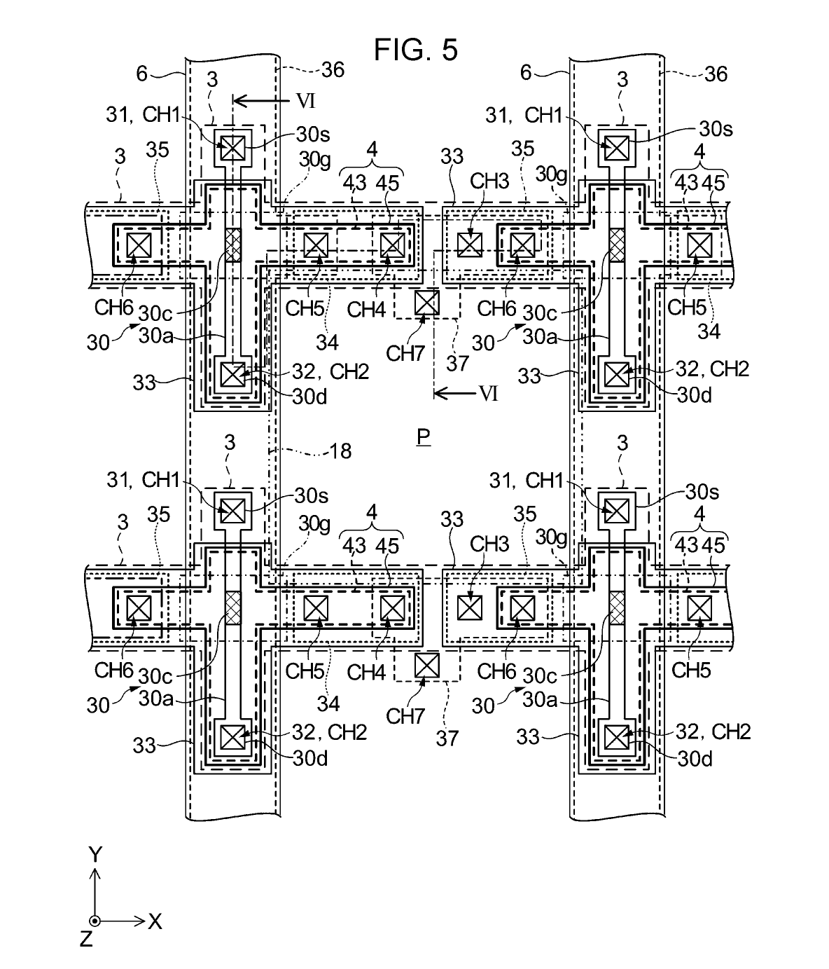

In addition, the capacitor 4 and a relay electrode 33 are disposed in the light shielding region S (refer to FIG. 5). The capacitor 4 and the relay electrode 33 are disposed so as to overlap with each other in plan view. The capacitor 4 includes an upper electrode 45 and a lower electrode 43 (refer to FIG. 5). The relay electrode 33 relays an electrical connection between the drain electrode 32 and the lower electrode 43 and the pixel electrode 18.

The scanning line 3, the data line 6, the upper electrode 45 and the lower electrode 43, and the relay electrode 33 are formed of a conductive member having a light shielding property, and at least a portion of the light shielding region S is configured with the components. The light shielding region S of the liquid crystal device 1 may be configured to include not only the wirings and the electrodes disposed on the element substrate 10 but also the light shielding layer 21 patterned in a lattice pattern on the counter substrate 20.

The TFT 30 (refer to FIG. 5) is disposed near an intersection of the light shielding region S. By providing the TFT 30 near the intersection of the light shielding region S which shields light, it is possible to prevent an erroneous operation of the TFT 30 and secure an aperture ratio of the opening region T.

Next, a configuration of the pixel P according to the present embodiment will be described with reference to FIGS. 5 and 6. FIG. 5 is a schematic plan view illustrating a configuration of the pixel of the liquid crystal device according to the first embodiment. FIG. 6 is a schematic sectional view taken along a line VI-VI of FIG. 5.

As illustrated in FIG. 5, the pixel electrode 18 having a substantially rectangular shape is disposed on the element substrate 10 for each pixel P. The scanning line 3 is disposed along a boundary between adjacent pixels P in the Y direction, that is, along the X direction. The scanning line 3 includes a main line portion which has a substantially linear shape and extends along the X direction and a portion which extends in the Y direction from the main line portion and overlaps with the semiconductor layer 30a of the TFT 30 in plan view. The data line 6 is disposed in a substantially linear shape along a boundary between adjacent pixels P in the X direction, that is, along the Y direction.

The TFT 30 is disposed in a region in which the scanning line 3 and the data line 6 intersect with each other. The TFT 30 includes the semiconductor layer 30a. The semiconductor layer 30a is disposed so as to overlap with the scanning line 3 and the data line 6 in plan view. The semiconductor layer 30a includes a channel region 30c, a source region 30s, and a drain region 30d.

A contact hole CH1 is provided so as to overlap with the data line 6 and the source region 30s of the semiconductor layer 30a in plan view. The data line 6 is electrically connected to the source region 30s of the semiconductor layer 30a via the contact hole CH1. A portion of the data line 6 that includes the contact hole CH1 is the source electrode 31.

A contact hole CH2 is provided so as to overlap with the drain region 30d of the semiconductor layer 30a in plan view. In addition, the relay electrode 33 is provided so as to overlap with the scanning line 3, the data line 6, and the drain region 30d of the semiconductor layer 30a in plan view.

The relay electrode 33 includes a portion extending along the X direction and a portion extending along the Y direction, and the portions intersect with each other at the intersection between the scanning line 3 and the data line 6. Thus, the relay electrode 33 has a “+” shape in plan view. The relay electrode 33 is electrically connected to the drain region 30d of the semiconductor layer 30a via the contact hole CH2. A portion of the relay electrode 33 that includes the contact hole CH2 is the drain electrode 32.

The capacitor 4 is disposed so as to overlap with the relay electrode 33 in plan view. Therefore, the capacitor 4 is disposed so as to overlap with the scanning line 3, the data line 6, and the drain region 30d of the semiconductor layer 30a in plan view. Similar to the relay electrode 33, the capacitor 4 includes a portion extending along the X direction and a portion extending along the Y direction, and the portions intersect with each other at the intersection between the scanning line 3 and the data line 6. Thus, the capacitor 4 has a “+” shape in plan view. Similar to the data line 6, the common potential line 36 is disposed along the Y direction.

As illustrated in FIG. 6, the element substrate 10 includes the substrate 11, the scanning line 3 as a light shielding layer, an insulating layer 12, the TFT 30, an insulating layer 13, the relay electrode 33 as an electrode, an insulating layer 14a, an insulating layer 14b, the capacitor 4, an insulating layer 15, the data line 6, a relay electrode 34, a relay electrode 35, an insulating layer 16, the common potential line 36, a relay electrode 37, and the pixel electrode 18. The substrate 11 has a plane including the X direction and the Y direction. Thus, a planar direction of the substrate 11 (hereinafter, simply referred to as the planar direction) includes the X direction and the Y direction. A thickness direction of the substrate 11 (hereinafter, simply referred to as the thickness direction) is the Z direction.

The scanning line 3 is made of, for example, a single metal including at least one metal such as aluminum (Al), titanium (Ti), chromium (Cr), tungsten (W), tantalum (Ta), or molybdenum (Mo), an alloy, a polysilicon, or a layer obtained by stacking the materials, and has a conductivity and a light shielding property. The scanning line 3 is disposed between the substrate 11 and the TFT 30. The scanning line 3 has a function of shielding light which is incident on the semiconductor layer 30a from the substrate 11.

The insulating layer 12 is disposed so as to cover the substrate 11 and the scanning line 3. The insulating layer 12 is made of, for example, silicon oxide (SiO₂) or silicon nitride (SiN). The subsequent insulating layers are also made of the same material as that of the insulating layer 12 unless otherwise specified.

The TFT 30 is disposed on the insulating layer 12. The TFT 30 includes the semiconductor layer 30a, a gate insulating film 30b, and the gate electrode 30g. The TFT 30 has, for example, a lightly doped drain (LDD) structure. The semiconductor layer 30a is made of, for example, a single crystal silicon film, a polycrystalline silicon film, or the like. The semiconductor layer 30a includes the channel region 30c, a junction region 30e, a junction region 30f, the source region 30s, and the drain region 30d.

The gate insulating film 30b is disposed so as to cover the semiconductor layer 30a and the insulating layer 12. The gate electrode 30g is disposed so as to be opposite to the channel region 30c with the gate insulating film 30b interposed therebetween. Although not illustrated, the gate electrode 30g is electrically connected to the scanning line 3. The insulating layer 13 is disposed so as to cover the gate insulating film 30b and the gate electrode 30g.

The relay electrode 33 is disposed on the insulating layer 13. The drain electrode 32 of the TFT 30 is formed by filling the contact hole CH2 which penetrates through the insulating layer 13 and the gate insulating film 30b and reaches the drain region 30d of the semiconductor layer 30a with a material forming the relay electrode 33. Thus, the relay electrode 33 is electrically connected to the drain region 30d of the semiconductor layer 30a. The relay electrode 33 is made of, for example, polysilicon, and has a conductivity and a light shielding property. The relay electrode 33 has a function of shielding light which is incident on the semiconductor layer 30a from the opposite side of the substrate 11. The subsequent relay electrodes are also made of the same material as that of the relay electrode 33.

The insulating layer 14a is disposed so as to cover the insulating layer 13 and the relay electrode 33. In the present embodiment, the insulating layer 14a is made of silicon oxide (SiO₂). The insulating layer 14b and the capacitor 4 are disposed on the insulating layer 14a. The insulating layer 14b is disposed in a region which overlaps with the capacitor 4 on the insulating layer 14a in plan view. In the present embodiment, the insulating layer 14b is made of silicon nitride (SiN). A groove 47 which reaches the relay electrode 33 is provided on the insulating layer 14a and the insulating layer 14b. The capacitor 4 is provided on the groove 47.

A structure of the capacitor 4 will be briefly described here, and details thereof will be described later. The capacitor 4 includes a lower electrode 43 disposed on the substrate 11, an insulator 46, a capacitor insulating film 44, and an upper electrode 45 disposed on the lower electrode 43 above the substrate 11. The lower electrode 43 is configured with a first capacitor electrode 41 and a second capacitor electrode 42. The first capacitor electrode 41 and the second capacitor electrode 42 are disposed so as to surround the periphery of the insulator 46.

The first capacitor electrode 41 is provided in the groove 47. In the groove 47, the first capacitor electrode 41 is brought into contact with the relay electrode 33. Thus, the lower electrode 43 (first capacitor electrode 41) is electrically connected to the drain region 30d of the semiconductor layer 30a via the relay electrode 33. The second capacitor electrode 42 is disposed above the first capacitor electrode 41 (+Z direction) so as to overlap with the first capacitor electrode 41 in plan view.

The upper electrode 45 is configured with a third capacitor electrode. In the following description, the upper electrode 45 may be referred to as the third capacitor electrode 45, or the upper electrode 45 and the third capacitor electrode may be expressed together. The third capacitor electrode 45 is disposed so as to cover the second capacitor electrode 42, a portion of the first capacitor electrode 41, and the insulating layer 14b by interposing the capacitor insulating film 44. The third capacitor electrode 45 is electrically connected to the common potential line 36 via the relay electrode 34 provided above the third capacitor electrode 45. Thus, the lower electrode 43 of the capacitor 4 is held at a drain potential, and the upper electrode 45 of the capacitor 4 is held at a common (COM) potential.

The first capacitor electrode 41, the second capacitor electrode 42, and the third capacitor electrode 45 are made of, for example, polysilicon, and have a conductivity and a light shielding property. The TFT 30 is disposed between the substrate 11 and the capacitor 4. Since the capacitor 4 is disposed above the TFT 30, the capacitor 4 contributes to shielding of light which is incident on the semiconductor layer 30a from above the TFT 30.

The capacitor insulating film 44 is disposed between the third capacitor electrode 45, the second capacitor electrode 42, a portion of the first capacitor electrode 41, and the insulating layer 14b. Thus, the insulating layer 14b is disposed between the insulating layer 14a and the capacitor insulating film 44. The capacitor insulating film 44 is made of, for example, silicon oxide (SiO₂), silicon nitride (SiN), or the like. The insulating layer 15 is disposed so as to cover the insulating layer 14a, the insulating layer 14b, and the capacitor 4.

The data line 6, the relay electrode 34, and the relay electrode 35 are disposed on the insulating layer 15. The source electrode 31 of the TFT 30 is formed by filling the contact hole CH1 which penetrates through the insulating layer 15, the insulating layer 14a, the insulating layer 13, and the gate insulating film 30b and reaches the source region 30s of the semiconductor layer 30a with a material forming the data line 6. Thus, the data line 6 is electrically connected to the source region 30s of the semiconductor layer 30a. The data line 6 is made of, for example, a single metal including at least one metal such as Al, Ti, Cr, W, Ta, or Mo, an alloy, a metal silicide, a polysilicide, a nitride, or a layer obtained by stacking the materials, and has a conductivity and a light shielding property.

The relay electrode 34 is electrically connected to the third capacitor electrode 45 of the capacitor 4 via a contact hole CH4 provided in the insulating layer 15. The relay electrode 35 is electrically connected to the relay electrode 33 via a contact hole CH3 penetrating through the insulating layer 15 and the insulating layer 14a. The insulating layer 16 is disposed so as to cover the insulating layer 15, the data line 6, the relay electrode 34, and the relay electrode 35.

The common potential line 36 and the relay electrode 37 are disposed on the insulating layer 16. The common potential line 36 is electrically connected to the relay electrode 34 via a contact hole CH5 provided in the insulating layer 16. The relay electrode 37 is electrically connected to the relay electrode 35 via a contact hole CH6 provided in the insulating layer 16. The insulating layer 17 is disposed so as to cover the insulating layer 16, the common potential line 36, and the relay electrode 37.

The pixel electrode 18 is disposed on the insulating layer 17. The pixel electrode 18 is electrically connected to the relay electrode 37 via a contact hole CH7 provided in the insulating layer 17. Thus, the pixel electrode 18 is electrically connected to the drain region 30d of the semiconductor layer 30a via the relay electrode 37, the relay electrode 35, and the relay electrode 33.

### Structure of Capacitor

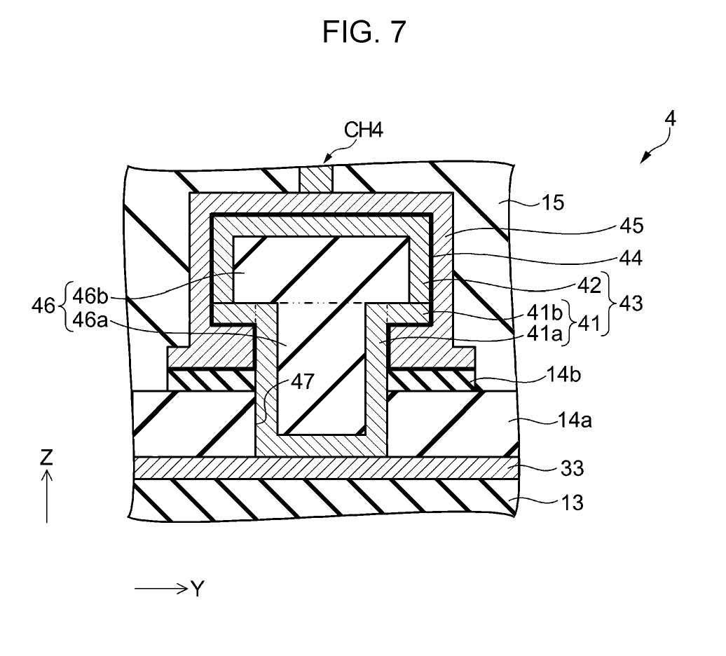

Subsequently, a structure of the capacitor according to the first embodiment will be described with reference to FIG. 7. FIG. 7 is a schematic sectional view illustrating a structure of the capacitor according to the first embodiment. FIG. 7 illustrates a section in a direction (the Y direction in FIG. 7) intersecting with an extending direction (the X direction in FIG. 7) of the capacitor 4. In FIG. 7, components other than a main portion are not illustrated. As described above, the capacitor 4 illustrated in FIG. 7 includes the lower electrode 43 (the first capacitor electrode 41 and the second capacitor electrode 42), the insulator 46, the capacitor insulating film 44, and the upper electrode (the third capacitor electrode) 45.

The first capacitor electrode 41 includes a recess-shaped portion 41a and a flange portion 41b. The recess-shaped portion 41a is disposed in the groove 47 penetrating through the insulating layer 14b and the insulating layer 14a. Although not illustrated, similar to the capacitor 4, the groove 47 has a “+” shape in plan view, the “+” shape in which a portion extending along the X direction and a portion extending along the Y direction intersect with each other. A bottom portion of the recess-shaped portion 41a is brought into contact with the relay electrode 33. Thereby, the first capacitor electrode 41 is held at the same potential (drain potential) as that of the relay electrode 33.

A side portion of the recess-shaped portion 41a extends from the groove 47 above the insulating layer 14b (+Z direction). The capacitor insulating film 44 and the third capacitor electrode 45 are disposed outside the side portion of the recess-shaped portion 41a in the Y direction that extends above the insulating layer 14b.

The flange portion 41b extends outside the recess-shaped portion 41a (in the +Y direction and the −Y direction) along the planar direction (Y direction in FIG. 7) from an upper end of the side portion of the recess-shaped portion 41a. In the Z direction, the flange portion 41b is separated from the insulating layer 14b, and the capacitor insulating film 44 and the third capacitor electrode 45 are disposed between the flange portion 41b and the insulating layer 14b.

The insulator 46 includes a first portion 46a and a second portion 46b. The first portion 46a is a portion disposed in the recess-shaped portion 41a of the first capacitor electrode 41. The second portion 46b is a portion protruding in a projection shape along the thickness direction (Z direction) from the upper end of the side portion of the recess-shaped portion 41a. In the present embodiment, the second portion 46b extends outside the recess-shaped portion 41a (in the +Y direction and the −Y direction) along the planar direction from an upper end of the first portion 46a. A width (a length in the Y direction) of the second portion 46b is wider than a width of the first portion 46a, and is narrower than a width of the first capacitor electrode 41 including the flange portion 41b. Thus, the second portion 46b overlaps with a portion of the flange portion 41b in plan view.

The second capacitor electrode 42 is disposed so as to cover an upper surface and side surfaces of the second portion 46b of the insulator 46. Thus, the second capacitor electrode 42 overlaps with the first capacitor electrode 41 in plan view. The second capacitor electrode 42 is connected to the flange portion 41b of the first capacitor electrode 41. Thereby, the second capacitor electrode 42 is held at the same potential (drain potential) as that of the first capacitor electrode 41.

The capacitor insulating film 44 is disposed so as to cover the second capacitor electrode 42 and an outer surface of a portion of the first capacitor electrode 41 including the flange portion 41b. More specifically, the capacitor insulating film 44 is disposed so as to cover an upper surface and side surfaces of the second capacitor electrode 42, a side surface and a lower surface of the flange portion 41b of the first capacitor electrode 41, a side surface of the side portion of the recess-shaped portion 41a of the first capacitor electrode 41 that extends above the insulating layer 14b, and the insulating layer 14b.

The third capacitor electrode 45 is disposed so as to cover the capacitor insulating film 44. That is, the third capacitor electrode 45 is disposed so as to cover the upper surface and the side surfaces of the second capacitor electrode 42, the side surface and the lower surface of the flange portion 41b of the first capacitor electrode 41, the side surface of the side portion of the recess-shaped portion 41a of the first capacitor electrode 41 that extends above the insulating layer 14b, and the insulating layer 14b by interposing the capacitor insulating film 44.

The third capacitor electrode 45 is connected to the relay electrode 34 (refer to FIG. 6) via the contact hole CH4. Thus, the third capacitor electrode 45 is held at the common (COM) potential. The insulating layer 14b overlaps with the third capacitor electrode 45 in plan view.

### Manufacturing Method of Electrooptical Device (Forming Method of Capacitor)

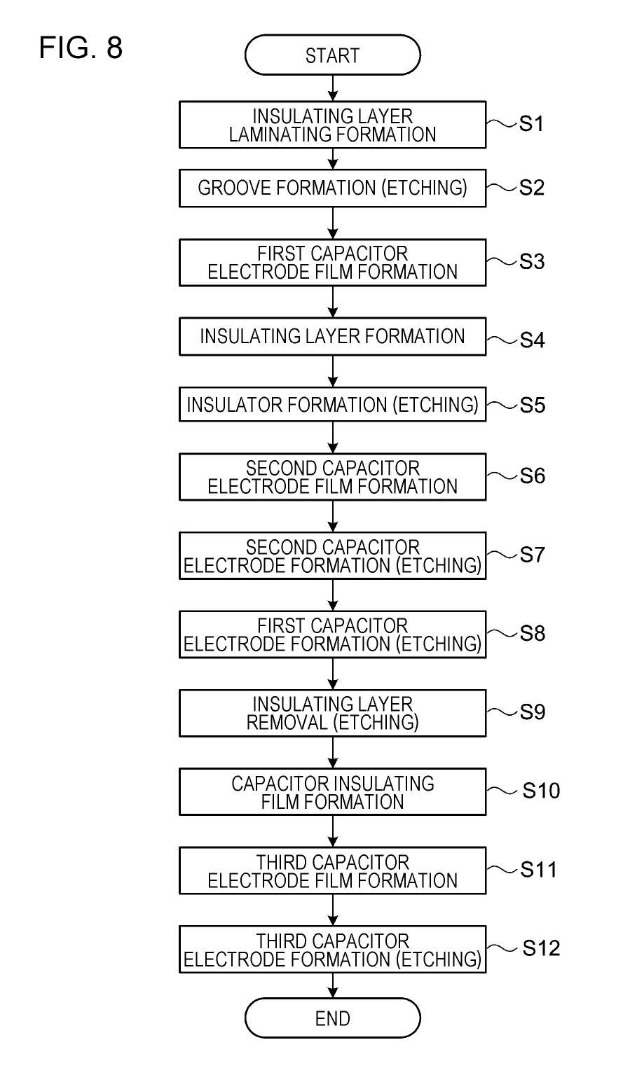

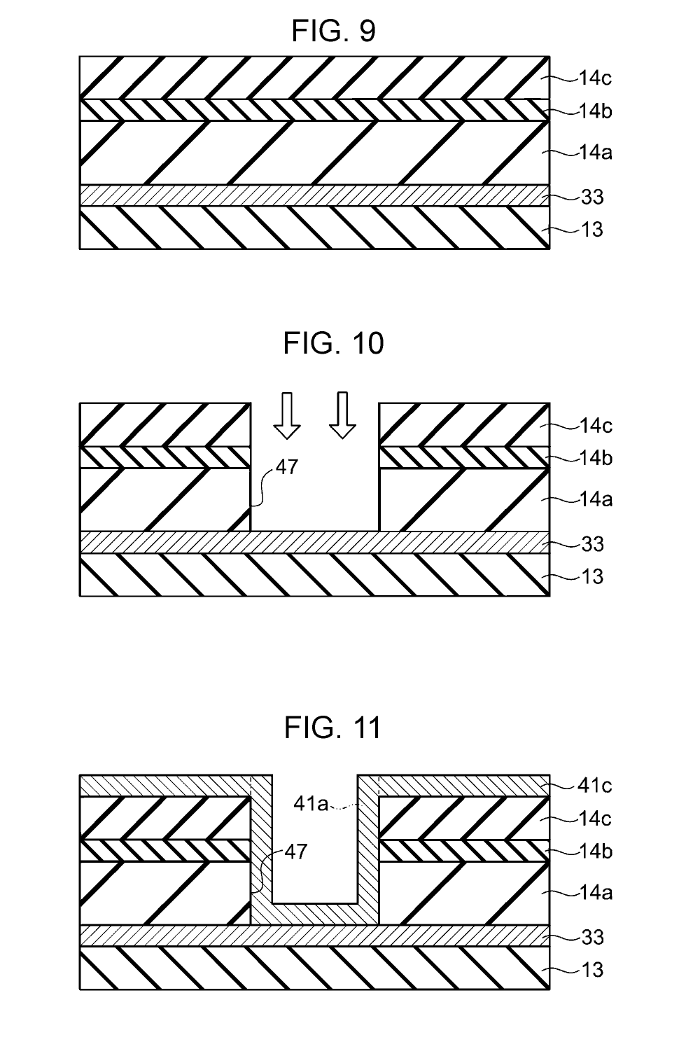

Next, as an example of a manufacturing method of the electrooptical device according to the first embodiment, a manufacturing method of the liquid crystal device 1 will be described. The manufacturing method of the liquid crystal device 1 has a feature in a forming method of the capacitor 4, and except for the forming method of the capacitor 4, a known method may be applied. Here, the forming method of the capacitor 4 will be described with reference to FIGS. 8 to 21. FIG. 8 is a flowchart illustrating the forming method of the capacitor according to the first embodiment. FIGS. 9 to 21 are schematic sectional views explaining the forming method of the capacitor according to the first embodiment. FIGS. 9 to 21 are schematic sectional views corresponding to FIG. 7, and components other than the main portion are not illustrated in FIGS. 9 to 21.

As illustrated in FIG. 8, the forming method of the capacitor according to the first embodiment includes an insulating layer stack formation step as a first step (step S1), a groove formation step as a second step (step S2), a first capacitor electrode film formation step (step S3) as a third step, an insulating layer formation step (step S4) as a fourth step, an insulator formation step (step S5) as a fifth step, a second capacitor electrode film formation step (step S6) as a sixth step, a second capacitor electrode formation step (step S7) as a seventh step, a first capacitor electrode formation step (step S8) as an eighth step, an insulating layer removing step (step S9) as a ninth step, a capacitor insulating film formation step (step S10) as a tenth step, a third capacitor electrode film formation step (step S11) as an eleventh step, and a third capacitor electrode formation step (step S12) as a twelfth step.

In the insulating layer stack formation step S1, as illustrated in FIG. 9, in a state where the insulating layer 13 is formed on the substrate 11 (refer to FIG. 6) and the relay electrode 33 is formed on the insulating layer 13, the insulating layer 14a as a first insulating layer, an insulating layer 14b as a second insulating layer, and an insulating layer 14c as a third insulating layer are formed by laminating in this order. In etching resistance, the insulating layer 14c is inferior to the insulating layer 14b below the insulating layer 14c. In the present embodiment, the insulating layer 14a and the insulating layer 14c are formed of silicon oxide (SiO₂), and the insulating layer 14b is formed of silicon nitride (SiN).

In the groove formation step S2, as illustrated in FIG. 10, the groove 47 extending from the insulating layer 14c to the insulating layer 14a is formed by anisotropic etching. Although not illustrated, a mask having an opening corresponding to a region where the groove 47 is to be formed is formed on the insulating layer 14c, and the insulating layer 14c, the insulating layer 14b, and the insulating layer 14a are etched by using the opening. Thereby, the groove 47 extending from the insulating layer 14c to the insulating layer 14a is formed, and the relay electrode 33 is exposed on a bottom portion of the groove 47.

In the first capacitor electrode film formation step S3, as illustrated in FIG. 11, a first capacitor electrode film 41c, which covers a front surface of the insulating layer 14c and includes the recess-shaped portion 41a in the groove 47, is formed. The first capacitor electrode film 41c may be formed by depositing polysilicon on the front surface of the insulating layer 14c and the inside of the groove 47, for example, by using a CVD method. A portion of the first capacitor electrode film 41c that is disposed in the groove 47 becomes the recess-shaped portion 41a.

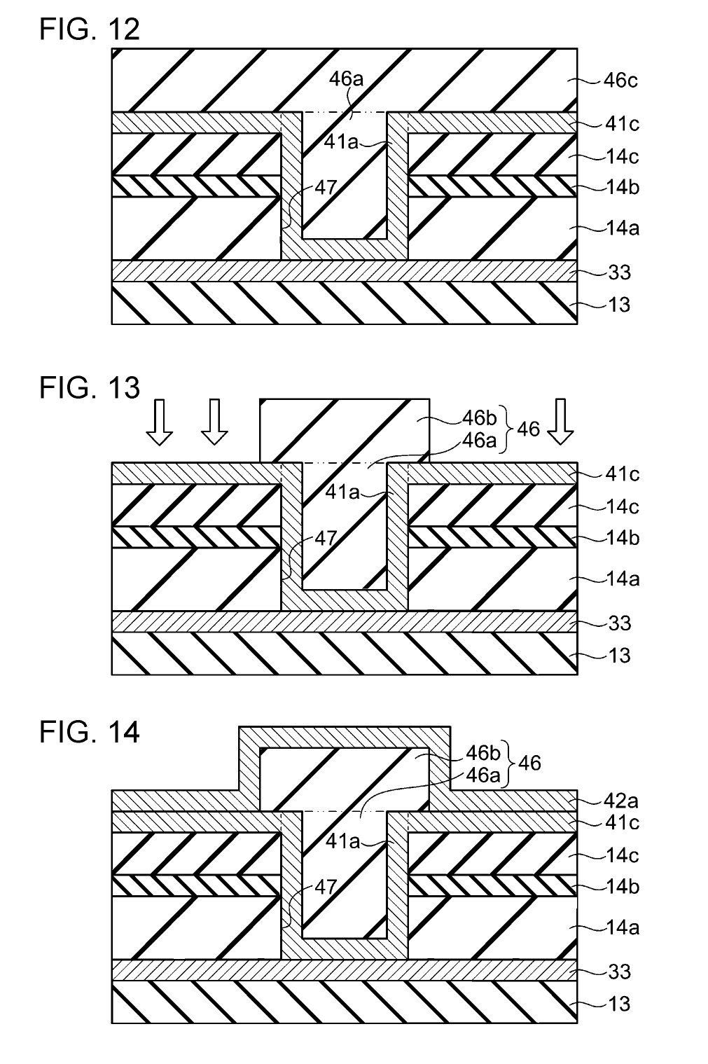

In the insulating layer formation step S4, as illustrated in FIG. 12, an insulating layer 46c as a fourth insulating layer is formed in the recess-shaped portion 41a and on the first capacitor electrode film 41c. In the present embodiment, the insulating layer 46c is formed so as to fill the recess-shaped portion 41a and cover the first capacitor electrode film 41c. The insulating layer 46c may be formed by depositing silicon oxide (SiO₂) on the front surface of the first capacitor electrode film 41c and the inside of the recess-shaped portion 41a, for example, by using a CVD method. A portion of the insulating layer 46c that is obtained by filling the inside of the recess-shaped portion 41a becomes the first portion 46a.

In the insulator formation step S5, as illustrated in FIG. 13, the insulating layer 46c is removed by using anisotropic etching, except for a portion of the insulating layer 46c that overlaps with the recess-shaped portion 41a of the first capacitor electrode film 41c and the periphery of the recess-shaped portion 41a in plan view. Thus, the insulator 46 including the first portion 46a and the second portion 46b is formed. Although not illustrated, a mask is formed on a region of the insulating layer 46c that overlaps with the recess-shaped portion 41a and the periphery of the recess-shaped portion 41a in plan view, and the insulating layer 46c is etched by using the mask.

Accordingly, the insulating layer 46c is removed except for the portion of the insulating layer 46c that overlaps with the mask in plan view, thereby forming the insulator 46 including the first portion 46a disposed in the recess-shaped portion 41a and the second portion 46b protruding in a projection shape from the upper end of the recess-shaped portion 41a above the first capacitor electrode film 41c. In addition, a portion of the first capacitor electrode film 41c is exposed, the portion corresponding to the removed portion of the insulating layer 46c. In the present embodiment, a width of the mask is set to be larger than a width of the recess-shaped portion 41a. As a result, the second portion 46b extends outside the recess-shaped portion 41a from the upper end of the first portion 46a along the planar direction.

In the second capacitor electrode film formation step S6, as illustrated in FIG. 14, the second capacitor electrode film 42a is formed so as to cover the second portion 46b of the insulator 46 and the exposed portion of the first capacitor electrode film 41c in step S5. The second capacitor electrode film 42a may be formed by depositing polysilicon on the front surface of the second portion 46b and the front surface of the first capacitor electrode film 41c, for example, by using a CVD method. Thereby, the second capacitor electrode film 42a is formed, the second capacitor electrode film 42a including a portion covering the upper surface and the side surfaces of the second portion 46b of the insulator 46 and a portion being brought into contact with the first capacitor electrode film 41c along the planar direction.

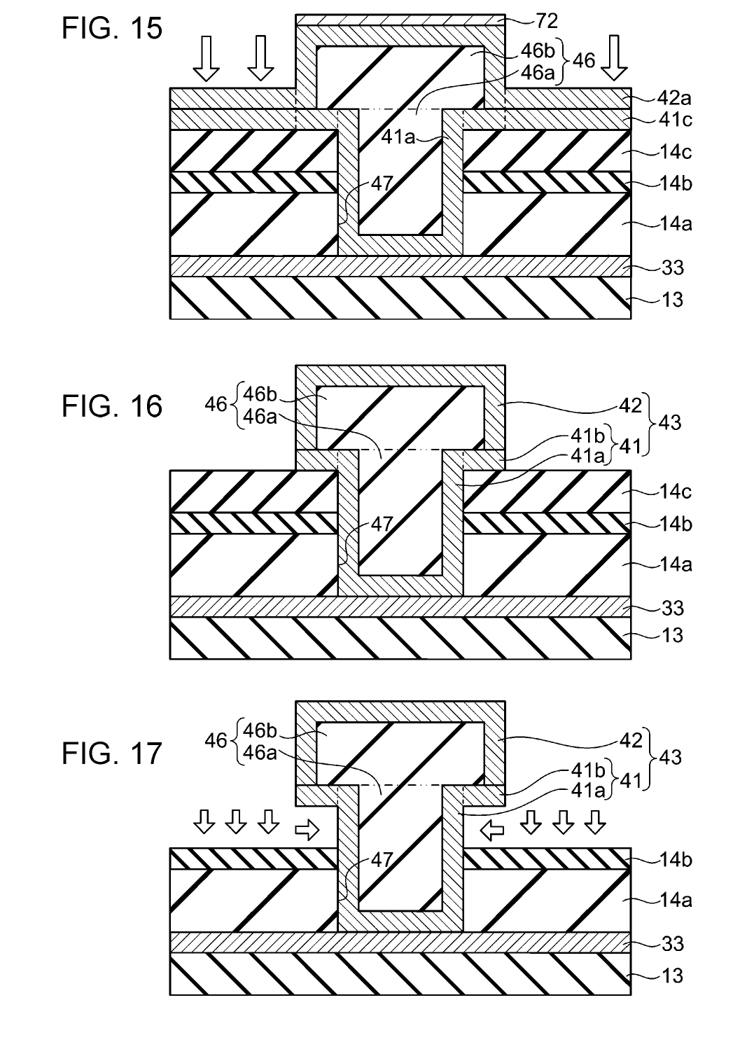

In the second capacitor electrode formation step S7, as illustrated in FIG. 15, the second capacitor electrode film 42a is removed by anisotropic etching except for a portion of the second capacitor electrode film 42a that covers the second portion 46b of the insulator 46 and is brought into contact with the first capacitor electrode film 41c, thereby forming the second capacitor electrode 42. In the first capacitor electrode formation step S8, as illustrated in FIG. 15, the first capacitor electrode film 41c is removed by anisotropic etching, except for a portion of the first capacitor electrode film 41c that overlaps with the second capacitor electrode 42 in plan view, thereby forming the first capacitor electrode 41.

In the present embodiment, the processing of step S7 and the processing of step S8 are performed continuously. As illustrated in FIG. 15, a mask 72 is formed on a portion of the second capacitor electrode film 42a that covers the second portion 46b of the insulator 46, and the second capacitor electrode film 42a and the first capacitor electrode film 41c are etched by using the mask 72. Thereby, as illustrated in FIG. 16, the portion of the second capacitor electrode film 42a that covers the upper surface and the side surfaces of the second portion 46b of the insulator 46 remains, and thus the second capacitor electrode 42 is formed. In addition, in the first capacitor electrode film 41c, the recess-shaped portion 41a and the flange portion 41b which is a portion extending outside the recess-shaped portion 41a (on the insulating layer 14c) along the planar direction remain, thereby forming the first capacitor electrode 41.

FIG. 16 illustrates a state where the mask 72 is removed after the anisotropic etching. The first capacitor electrode 41 and the second capacitor electrode 42 overlap with each other in plan view, and are connected to each other at the flange portion 41b. A length of the flange portion 41b can be controlled by adjusting the width of the second portion 46b of the insulator 46 with respect to the width of the recess-shaped portion 41a in step S5. In addition, the length of the flange portion 41b can be controlled by adjusting a width of the second capacitor electrode 42 in step S7.

In the insulating layer removing step S9, as illustrated in FIG. 17, the insulating layer 14c is removed by isotropic etching. In the present embodiment, in step S1, the insulating layer 14b below the insulating layer 14c is formed of silicon nitride (SiN), and the insulating layer 14c is formed of silicon oxide (SiO₂) which is inferior to the insulating layer 14b in etching resistance. In step S9, the isotropic etching is performed under an etching condition in which the insulating layer 14c can be selectively removed. Thereby, the insulating layer 14c is removed, and thus the lower surface of the flange portion 41b of the first capacitor electrode 41, the side surface of the portion of the recess-shaped portion 41a that is positioned above the insulating layer 14b, and the insulating layer 14b are exposed.

In step S9, the insulating layer 14b functions as an etching stopper, and thus the flange portion 41b of the first capacitor electrode 41 and the portion of the recess-shaped portion 41a that is positioned above the insulating layer 14b are reliably exposed, thereby suppressing excess etching. A length (height) of the portion of the recess-shaped portion 41a that is exposed above the insulating layer 14b can be controlled by a thickness of the insulating layer 14c formed in step S1. The mask 72 formed in step S7 may be removed after the processing of step S9.

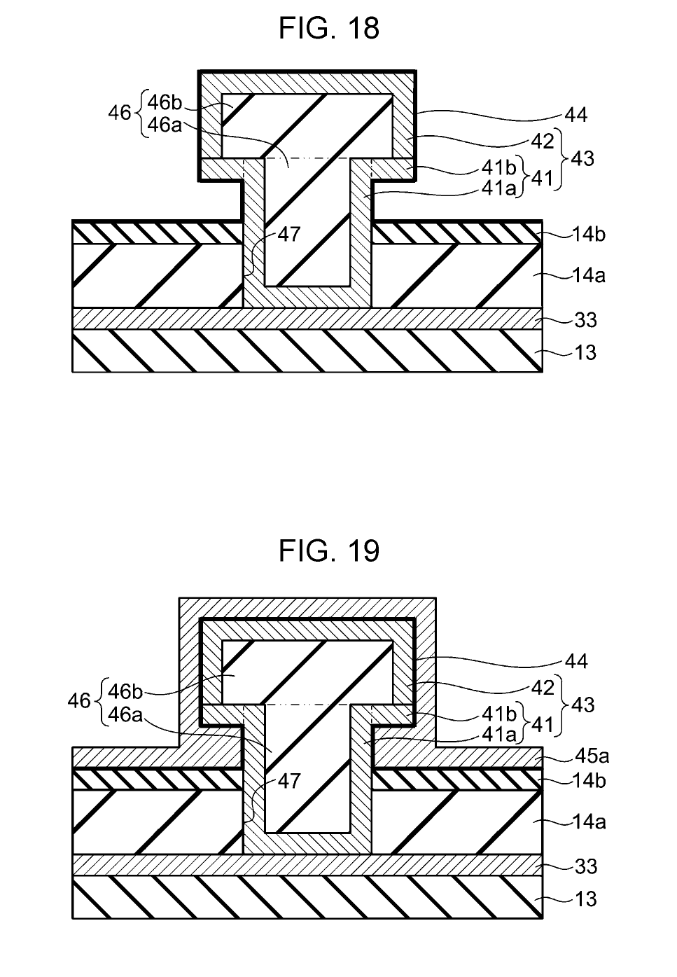

In the capacitor insulating film formation step S10, as illustrated in FIG. 18, the capacitor insulating film 44 is formed so as to cover the second capacitor electrode 42 and the outer surface of the portion of the first capacitor electrode 41 that is positioned above the insulating layer 14b. The capacitor insulating film 44 is formed, for example, by depositing silicon oxide (SiO₂), silicon nitride (SiN), or the like on the upper surface and the side surfaces of the second capacitor electrode 42, the side surface and the lower surface of the flange portion 41b, the side surface of the portion of the recess-shaped portion 41a that is positioned above the insulating layer 14b, and the front surface of the insulating layer 14b, by using a CVD method.

In the third capacitor electrode film formation step S11, as illustrated in FIG. 19, the third capacitor electrode film 45a is formed so as to cover the capacitor insulating film 44. The third capacitor electrode film 45a may be formed, for example, by depositing polysilicon on the front surface of the capacitor insulating film 44 by using a CVD method. Thereby, the third capacitor electrode film 45a is formed so as to cover the upper surface and the side surfaces of the second capacitor electrode 42, the side surface and the lower surface of the flange portion 41b, the side surface of the portion of the recess-shaped portion 41a that is positioned above the insulating layer 14b, and the front surface of the insulating layer 14b by interposing the capacitor insulating film 44.

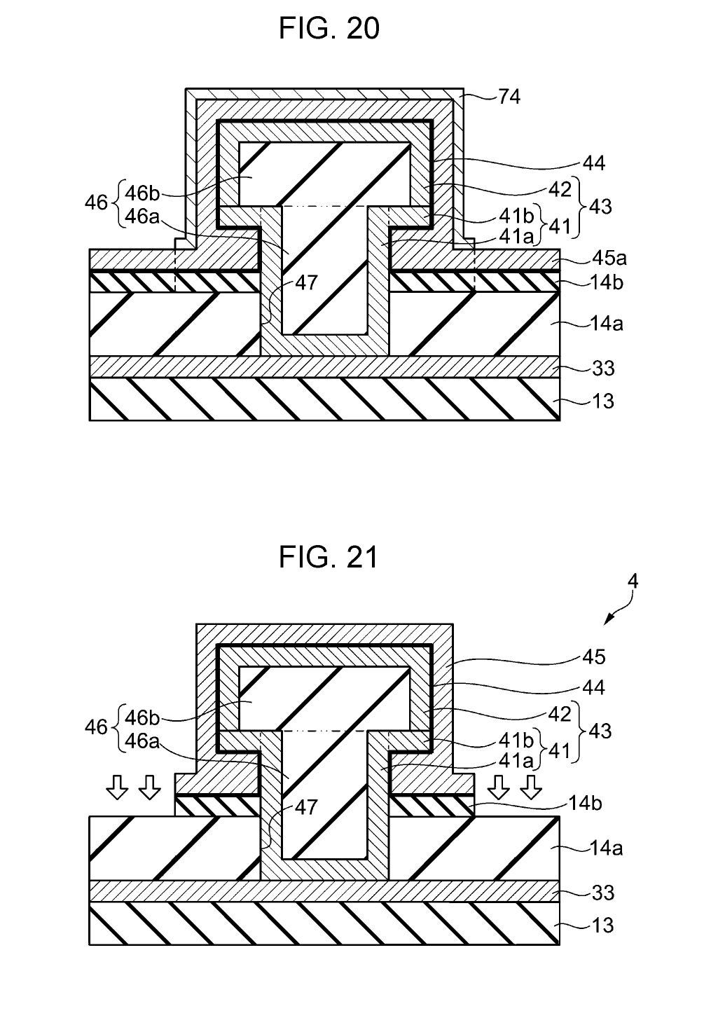

In the third capacitor electrode formation step S12, the third capacitor electrode film 45a is removed by anisotropic etching except for a portion of the third capacitor electrode film 45a which covers the second capacitor electrode 42 and the portion of the first capacitor electrode 41 that is positioned above the insulating layer 14b by interposing the capacitor insulating film 44, thereby forming the third capacitor electrode 45. As illustrated in FIG. 20, a mask 74 is formed on the portion of the third capacitor electrode film 45a covering the second capacitor electrode 42 and the first capacitor electrode 41, and the third capacitor electrode film 45a and the capacitor insulating film 44 are etched by using the mask 74. A width of the mask 74 may be wider than a width of the portion of the third capacitor electrode film 45a covering the second capacitor electrode 42 and the first capacitor electrode 41.

Thereby, as illustrated in FIG. 21, the portion of the third capacitor electrode film 45a covering the second capacitor electrode 42 and the first capacitor electrode 41 remains, and thus the third capacitor electrode 45 is formed. In addition, a portion of the insulating layer 14b that overlaps with the third capacitor electrode 45 in plan view remains. In this manner, the capacitor 4 is formed.

After step S12, the insulating layer 15 is formed so as to cover the capacitor 4, the insulating layer 14a, and the insulating layer 14b. Subsequently, the data line 6, the relay electrode 34, the relay electrode 35, the insulating layer 16, the common potential line 36, the relay electrode 37, and the pixel electrode 18 are formed on the insulating layer 15. Thereby, the element substrate 10 is formed.

According to the configuration and the manufacturing method of the capacitor 4 according to the first embodiment, the following effects can be obtained.

(1) In the capacitor 4, the first capacitor electrode 41 and the second capacitor electrode 42 function as the lower electrode 43 disposed on the substrate 11, and the third capacitor electrode 45 functions as the upper electrode 45 disposed on the lower electrode 43 above the substrate 11. The capacitance of the capacitor 4 is determined based on an area in which the lower electrode 43 and the upper electrode 45 are opposite to each other with the capacitor insulating film 44 interposed therebetween. Similar to the first capacitor electrode described in JP-A-2015-94880, the second capacitor electrode 42 of the lower electrode 43 covers the upper surface and the side surfaces of the second portion 46b of the insulator 46 that protrudes in a projection shape, and is opposite to the third capacitor electrode 45 as the upper electrode. A portion of the first capacitor electrode 41 of the lower electrode 43 that includes the flange portion 41b connected to the second capacitor electrode 42, is opposite to the third capacitor electrode 45. That is, an area of the lower electrode 43 opposite to the upper electrode 45 of the capacitor 4 is larger than that in the configuration described in JP-A-2015-94880, by an area of the portion of the first capacitor electrode 41 that includes the flange portion 41b. On the other hand, since the second capacitor electrode 42 is disposed so as to overlap with the first capacitor electrode 41 in plan view, even when the total area in which the lower electrode 43 and the upper electrode 45 are opposite to each other is increased by addition of the portion of the first capacitor electrode 41, a planar area does not change. Thereby, as compared with the configuration described in JP-A-2015-94880, it is possible to increase a holding capacitance per unit planar area of the capacitor 4. Therefore, it is possible to realize a high aperture ratio of the liquid crystal device 1 and secure a holding capacitance of the liquid crystal device 1.

(2) The second portion 46b of the insulator 46 overlaps with the flange portion 41b of the first capacitor electrode 41 in plan view. Thus, as compared with a case where the second portion 46b of the insulator 46 does not overlap with the flange portion 41b of the first capacitor electrode 41 in plan view, a length of the flange portion 41b, which overlaps with the second capacitor electrode 42 covering the second portion 46b in plan view, becomes longer. Therefore, since the total area in which the lower electrode 43 and the upper electrode 45 are opposite to each other becomes larger than the planar area of the lower electrode 43 (the first capacitor electrode 41 and the second capacitor electrode 42), it is possible to further increase the holding capacitance per unit planar area of the capacitor 4. In addition, it is possible to control the length of the flange portion 41b by adjusting a length with which the second portion 46b of the insulator 46 overlaps with the flange portion 41b of the first capacitor electrode 41 in plan view.

(3) The third capacitor electrode 45 is disposed to be opposite to the portion of the recess-shaped portion 41a that is positioned above the insulating layer 14b in addition to the flange portion 41b of the first capacitor electrode 41. Since the recess-shaped portion 41a of the first capacitor electrode 41 is inside the flange portion 41b in plan view, it is possible to increase the total area in which the lower electrode 43 and the upper electrode 45 are opposite to each other, without increasing the planar area of the capacitor 4.

(4) Since the relay electrode 33 provided between the substrate 11 and the capacitor 4 is brought into contact with the bottom portion of the recess-shaped portion 41a of the first capacitor electrode 41, it is possible to use the relay electrode 33 as a relay electrode for relaying an electrical connection to the first capacitor electrode 41 disposed in the groove 47 of the insulating layer 14a and the insulating layer 14b.

(5) Since the capacitor 4 is disposed so as to overlap with the scanning line (light shielding layer) 3 in plan view, the aperture ratio of the pixel P is not reduced. In addition, since the scanning line 3 is disposed below the TFT 30 on the substrate 11 and the capacitor 4 is disposed above the TFT 30 on the substrate 11, the capacitor 4 can contribute to the shielding of the light from above the TFT 30.

(6) By performing the processing from step S1 to step S12, it is possible to increase the holding capacitance per unit planar area of the capacitor 4. Thus, it is possible to manufacture the liquid crystal device 1 capable of realizing the high aperture ratio and securing the holding capacitance. In step S5, by adjusting the width of the second portion 46b of the insulator 46 with respect to the width of the first portion 46a disposed in the recess-shaped portion 41a of the first capacitor electrode film 41c, it is possible to control a planar size of the second capacitor electrode 42 to be formed in step S7 and a length of the flange portion 41b of the first capacitor electrode 41 to be formed in step S8. In step S9, since the insulating layer 14b functions as an etching stopper, the flange portion 41b of the first capacitor electrode 41 and the portion of the recess-shaped portion 41a that is positioned above the insulating layer 14b are reliably exposed. Thus, it is possible to suppress excess etching. By adjusting the thickness of the insulating layer 14c formed on the insulating layer 14b in step S1, it is possible to control the length of the portion of the first capacitor electrode 41 that is exposed above the insulating layer 14b in step S9. In step S10 and step S11, the third capacitor electrode film 45a is formed so as to cover the second capacitor electrode 42 and the outer surface of the portion of the first capacitor electrode 41 including the flange portion 41b that is positioned above the insulating layer 14b by interposing the capacitor insulating film 44. Thus, as compared with the capacitor described in JP-A-2015-94880, it is possible to increase the total area in which the lower electrode 43 and the upper electrode (third capacitor electrode) 45 are opposite to each other, without increasing the planar area of the capacitor 4.

### Second Embodiment

The second embodiment is different from the first embodiment in a sectional shape of the capacitor, and is the same as the first embodiment in the basic configuration of the liquid crystal device. Here, a structure of the capacitor according to the second embodiment and a manufacturing method of the capacitor will be described.

### Structure of Capacitor

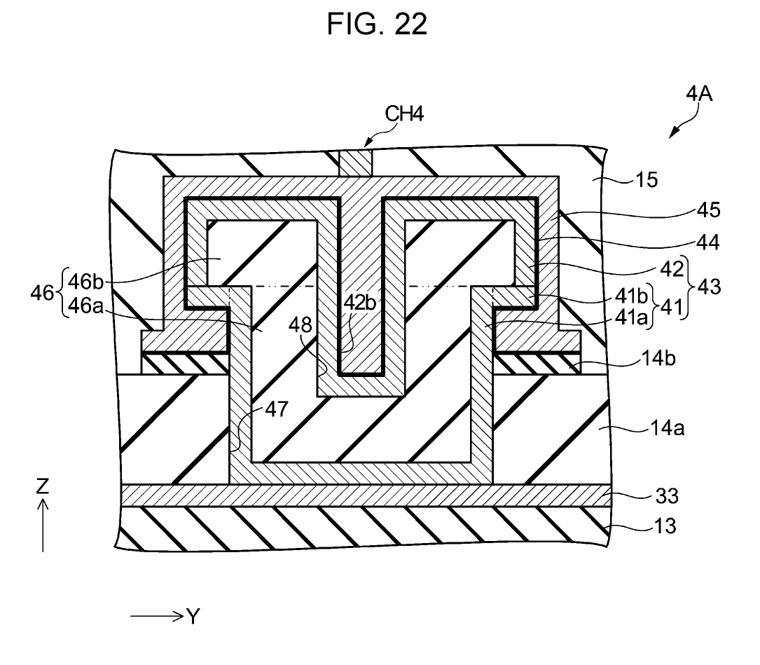

The structure of the capacitor according to the second embodiment will be described with reference to FIG. 22. FIG. 22 is a schematic sectional view illustrating the structure of the capacitor according to the second embodiment.

As illustrated in FIG. 22, the capacitor 4A according to the second embodiment includes the lower electrode 43 (the first capacitor electrode 41 and the second capacitor electrode 42), the insulator 46, the capacitor insulating film 44, and the upper electrode (third capacitor electrode) 45, and is different from the capacitor 4 according to the first embodiment in the sectional shape. Here, the difference from the first embodiment will be described.

The second embodiment corresponds to a case where a width of the groove 47 is wider than that of the first embodiment. For example, in a case where a width of the light shielding region S (refer to FIG. 4) is wider than that of the first embodiment, the width of the groove 47 becomes wider, and thus the planar area of the capacitor 4A is increased. Therefore, it is possible to further increase the total area in which the upper electrode 45 and the lower electrode 43 are opposite to each other. On the other hand, when the width of the groove 47 becomes wider compared to the thickness of the insulating layer 46c for forming the insulator 46, the groove 47 in which the first capacitor electrode film 41c is formed cannot be filled with the material of the insulating layer 46c.

In the capacitor 4A according to the second embodiment, the insulator 46 has a recess-shaped section, and includes a recess portion 48 at the center in the planar direction. In other words, the insulator 46 has a U-shaped section. The recess portion 48 is formed, for example, from the second portion 46b to the first portion 46a of the insulator 46. Thus, the first portion 46a also has a U-shaped section. The second portion 46b extends outside the recess-shaped portion 41a of the first capacitor electrode (in the +Y direction and the −Y direction) from the U-shaped first portion 46a.

The second capacitor electrode 42 is disposed so as to cover the upper surface and the outer surface of the second portion 46b of the insulator 46, and a bottom surface and inner surfaces of the recess portion 48 formed from the second portion 46b to the first portion 46a, and to overlap with the first capacitor electrode 41 in plan view. Thus, the second capacitor electrode 42 also includes a recessed portion 42b corresponding to the recess portion 48. Therefore, as compared with the first embodiment, a planar area of the second capacitor electrode 42 increases by an area corresponding to the bottom surface of the recess portion 48 of the insulator 46, while the total area of the second capacitor electrode 42 increases by an area corresponding to the bottom surface and the inner surfaces of the recess portion 48 of the insulator 46.

The third capacitor electrode 45 is disposed so as to cover the upper surface and the outer surface of the second capacitor electrode 42, the side surface and the lower surface of the flange portion 41b of the first capacitor electrode 41, the side surface of the side portion of the recess-shaped portion 41a of the first capacitor electrode 41 that extends above the insulating layer 14b, and the insulating layer 14b and to fill the recessed portion 42b of the second capacitor electrode 42 by interposing the capacitor insulating film 44. Thus, a planar area of the third capacitor electrode 45 also increases by an area corresponding to a bottom surface of the recessed portion 42b of the second capacitor electrode 42, while the total area of the third capacitor electrode 45 increases by an area corresponding to the bottom surface and inner surfaces of the recessed portion 42b of the second capacitor electrode 42.

Therefore, in the capacitor 4A according to the second embodiment, as compared with the capacitor 4 according to the first embodiment, it is possible to increase a ratio of the total area in which the lower electrode 43 and the upper electrode 45 are opposite to each other with respect to the planar area of the capacitor 4A. Thereby, it possible to further increase the holding capacitance per unit planar area of the capacitor.

### Forming Method of Capacitor

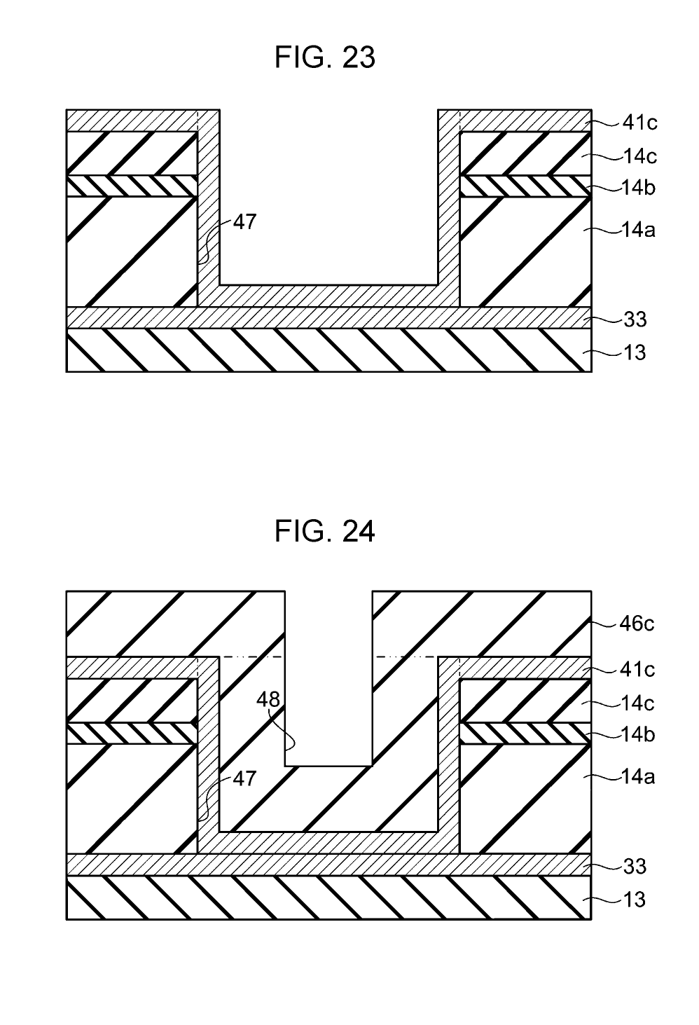

Next, a forming method of the capacitor according to the second embodiment will be described with reference to FIGS. 23 to 26. FIGS. 23 to 26 are schematic sectional views explaining the forming method of the capacitor according to the second embodiment.

FIG. 23 corresponds to FIG. 11 according to the first embodiment, and illustrates a state where the processing from step S1 to step S3 is performed. As illustrated in FIG. 23, the width of the groove 47 which is formed from the insulating layer 14c to the insulating layer 14a is wider than that in the first embodiment.

FIG. 24 corresponds to FIG. 12 according to the first embodiment, and illustrates a state where the processing of step S4 is performed. As illustrated in FIG. 24, since the width of the groove 47 is wider compared to the thickness of the insulating layer 46c, the groove 47 in which the first capacitor electrode film 41c is formed cannot be filled with the material of the insulating layer 46c. As a result, the recess portion 48 is formed on a portion of the insulating layer 46c corresponding to the groove 47.

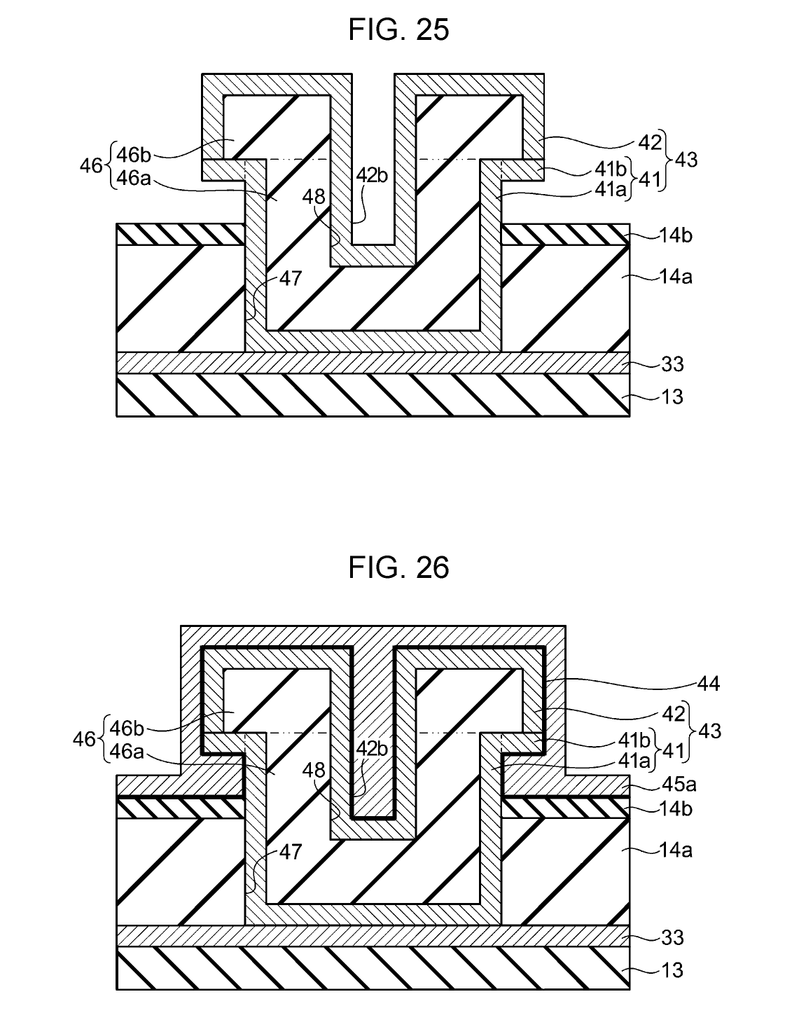

FIG. 25 corresponds to FIG. 17 according to the first embodiment, and illustrates a state where the processing from step S5 to step S9 is performed. The second capacitor electrode 42 formed in step S7 covers not only the upper surface and the outer surface of the second portion 46b of the insulator 46, but also the bottom surface and the inner surfaces of the recess portion 48 formed from the second portion 46b to the first portion 46a. Thereby, as illustrated in FIG. 25, the recessed portion 42b corresponding to the recess portion 48 is formed on the second capacitor electrode 42.

FIG. 26 corresponds to FIG. 19 according to the first embodiment, and illustrates a state where the processing of step S10 and step S11 is performed. As illustrated in FIG. 26, the third capacitor electrode film 45a formed in step S11 covers not only the upper surface and the outer surface of the second capacitor electrode 42, the side surface and the lower surface of the flange portion 41b of the first capacitor electrode 41, the side surface of the side portion of the recess-shaped portion 41a of the first capacitor electrode 41 that extends above the insulating layer 14b, and the insulating layer 14b, but also the bottom surface and the inner surfaces of the recessed portion 42b of the second capacitor electrode 42 by interposing the capacitor insulating film 44.

FIG. 26 illustrates a state where the third capacitor electrode film 45a is formed so as to fill the recessed portion 42b of the second capacitor electrode 42. On the other hand, the third capacitor electrode film 45a may be formed to include a recess portion corresponding to the recessed portion 42b of the second capacitor electrode 42. After that, similar to the first embodiment, by performing the processing of step S12, the capacitor 4A illustrated in FIG. 22 is formed.

According to the configuration and the manufacturing method of the capacitor 4A according to the second embodiment, the following effects can be obtained.

The second capacitor electrode 42 is disposed so as to cover the bottom surface and the inner surfaces of the recess portion 48 which is recessed from the second portion 46b to the first portion 46a of the insulator 46. Thus, the planar area of the second capacitor electrode 42 increases by an area corresponding to the bottom surface of the recess portion 48 of the insulator 46, while the total area of the second capacitor electrode 42 increases by an area corresponding to the bottom surface and the inner surfaces of the recess portion 48 of the insulator 46. Similarly, the total area of the third capacitor electrode 45, which covers the second capacitor electrode 42 by interposing the capacitor insulating film 44, also increases. Thereby, it possible to further increase the holding capacitance per unit planar area of the capacitor 4A.

### Third Embodiment

The third embodiment is different from the first embodiment in a structure of the capacitor, and is the same as the first embodiment in the basic configuration of the liquid crystal device. Here, the structure of the capacitor according to the third embodiment will be described.

### Structure of Capacitor

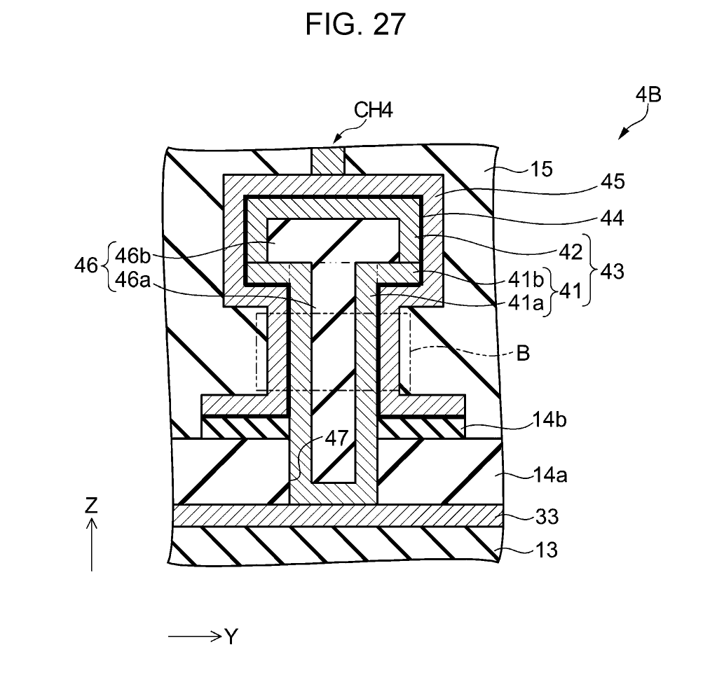

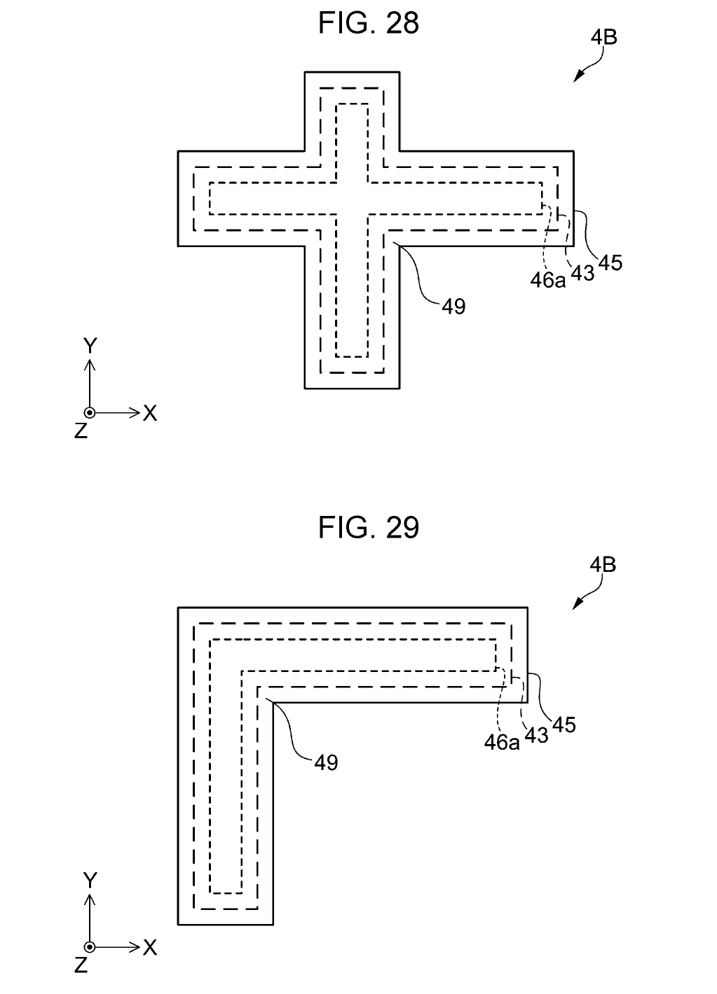

The structure of the capacitor according to the third embodiment will be described with reference to FIGS. 27, 28, and 29. FIG. 27 is a schematic sectional view illustrating the structure of the capacitor according to the third embodiment. FIGS. 28 and 29 are schematic plan views illustrating planar shapes of the capacitor according to the third embodiment.

As illustrated in FIG. 27, the capacitor 4B according to the third embodiment includes the lower electrode 43 (the first capacitor electrode 41 and the second capacitor electrode 42), the insulator 46, the capacitor insulating film 44, and the upper electrode (third capacitor electrode) 45, and is different from the capacitor 4 according to the first embodiment in the sectional shape. Here, the difference from the first embodiment will be described.

The third embodiment corresponds to the case where the depth of the groove 47 in which the capacitor 4B is formed is deep relative to its width. For example, in a case where the width of the light shielding region S (refer to FIG. 4) is narrower than that in the first embodiment, since the width of the groove 47 becomes narrower, a ratio of a depth of the groove 47 (a length in the Z direction of FIG. 27) with respect to the width of the groove 47 (a length in the Y direction of FIG. 27) increases. In addition, even in a case where intermediate layers of the element substrate 10 (the insulating layer 14a, the insulating layer 15, and the like) are thick, the ratio of the depth of the groove 47 with respect to the width of the groove 47 increases. When the ratio of the depth of the groove 47 with respect to the width of the groove 47 increases, a ratio of a height of the capacitor 4B (a length in the Z direction of FIG. 27) with respect to a width of the capacitor 4B increases.

In the capacitor 4B according to the third embodiment, in a portion B, a ratio of a height of the recess-shaped portion 41a of the first capacitor electrode 41 with respect to the width of the groove 47 is larger than that in the first embodiment. For this reason, even when the width of the capacitor 4A becomes narrow in the portion of the recess-shaped portion 41a that is positioned above the insulating layer 14b, the area in which the lower electrode 43 and the upper electrode 45 are opposite to each other can be relatively increased. Thus, it is possible to secure the holding capacitance per unit planar area of the capacitor 4.

On the other hand, when the capacitor 4B has such a sectional shape, in a state where the processing of step S12 is completed and the capacitor 4B is formed (a state before the insulating layer 15 illustrated in FIG. 27 is formed), it is concerned that a mechanical strength of the capacitor 4B is reduced in the portion B illustrated in FIG. 27. More specifically, when a planar shape of the capacitor 4B is a shape extending only in one direction of the X direction and the Y direction, in a state where the processing of step S12 is completed, for example, there is a concern that the portion B is damaged when a force is applied to the capacitor 4B from the +Y direction or the −Y direction due to a physical contact, impact, vibration, or the like.

As illustrated in FIG. 28, the capacitor 4B includes an intersection portion 49 in which a portion extending along the X direction of the planar direction and a portion extending along the Y direction of the planar direction are connected to each other in a “+” shape. When the capacitor 4B has the planar shape including the intersection portion 49, for example, in a case where a force is applied along the Y direction, the portion extending along the Y direction that is not likely to be affected by the force supports the portion extending along the X direction, and in a case where a force is applied along the X direction, the portion extending along the X direction that is not likely to be affected by the force supports the portion extending along the Y direction. Thus, it is possible to reduce a risk of damage to the capacitor 4B.

As illustrated in FIG. 5, the capacitor 4 according to the first embodiment also has the planar shape in which the portion extending along the X direction and the portion extending along the Y direction are connected to each other in a “+” shape. Therefore, as long as the capacitor 4 according to the first embodiment has the planar shape, even when the capacitor 4B according to the third embodiment has the sectional shape, it is possible to reduce the risk of damage to the capacitor 4B.

The planar shape of the capacitor 4B is not limited to a shape in which the portion extending along the X direction and the portion extending along the Y direction are connected to each other in a “+” shape. As illustrated in FIG. 29, the capacitor 4B may include an intersection portion 49 in which the portion extending along the X direction and the portion extending along the Y direction are connected to each other in an L shape. Even in the case of the planar shape, it is possible to reduce the risk of damage to the capacitor 4B.

In FIG. 27, although the capacitor 4B has a constricted shape in the B portion, the constricted shape of the capacitor 4B in the B portion may be relaxed, for example, by making the thickness of the third capacitor electrode 45 thick.

According to the configuration of the capacitor 4B according to the third embodiment, the following effects can be obtained.

Even in a case where the ratio of the depth of the groove 47 with respect to the width of the groove 47 is large, in other words, the ratio of the height of the capacitor 4B with respect to the width of the capacitor 4B is large and as a result there is a concern that a mechanical strength of the capacitor is reduced, by providing the intersection portion 49 in which the portion extending along the X direction and the portion extending along the Y direction are connected to each other, it is possible to suppress a reduction in the mechanical strength of the capacitor 4B.

### Fourth Embodiment

### Electronic Apparatus

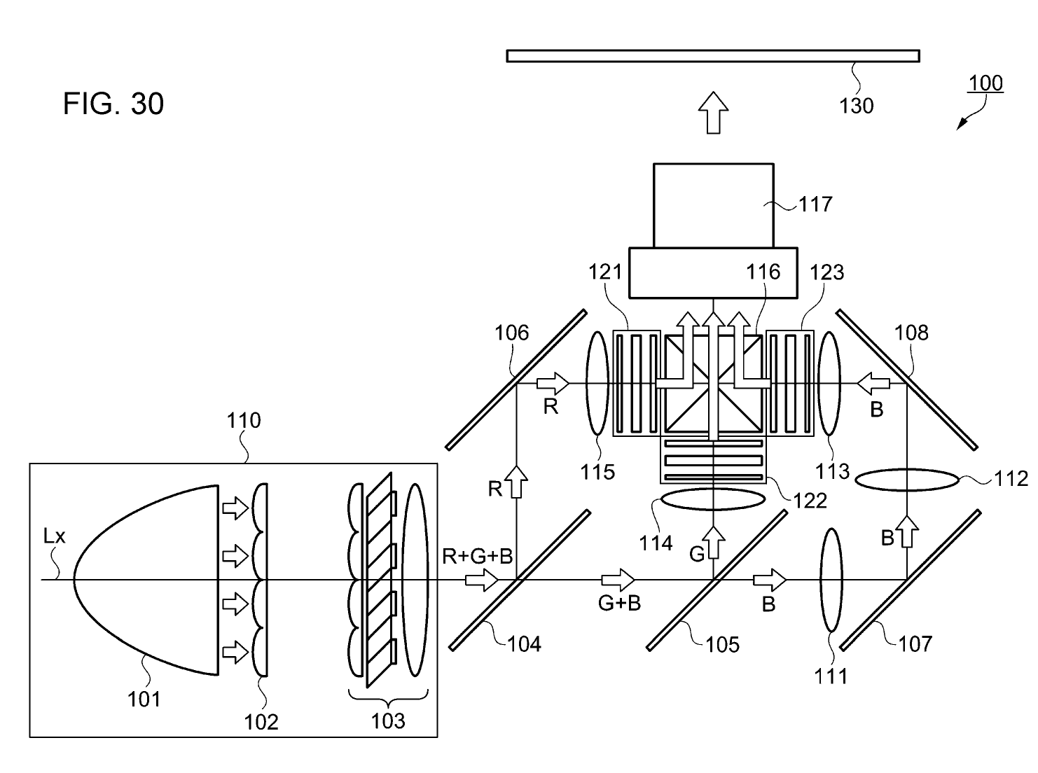

Next, an electronic apparatus according to a fourth embodiment will be described with reference to FIG. 30. FIG. 30 is a schematic diagram illustrating a configuration of a projector as an electronic apparatus according to the fourth embodiment.

As illustrated in FIG. 30, a projector (a projection-type display apparatus) 100 as an electronic apparatus according to the fourth embodiment includes a polarization illumination device 110, two dichroic mirrors 104 and 105 as light dispersion elements, three reflection mirrors 106, 107, and 108, five relay lenses 111, 112, 113, 114, and 115, three liquid crystal light valves 121, 122, and 123, a cross dichroic prism 116 as a light combination element, and a projection lens 117.

The polarization illumination device 110 includes a lamp unit 101 as a white light source such as an ultrahigh pressure mercury lamp or a halogen lamp, an integrator lens 102, and a polarization conversion element 103. The lamp unit 101, the integrator lens 102, and the polarization conversion element 103 are disposed along a system optical axis Lx.

The dichroic mirror 104 reflects red light (R) of polarization light flux emitted from the polarization illumination device 110, and transmits green light (G) and blue light (B) of the polarization light flux. The other dichroic mirror 105 reflects the green light (G) transmitted through the dichroic mirror 104, and transmits the blue light (B).

The red light (R) reflected by the dichroic mirror 104 is reflected by the reflection mirror 106, and then is incident on the liquid crystal light valve 121 via the relay lens 115. The green light (G) reflected by the dichroic mirror 105 is incident on the liquid crystal light valve 122 via the relay lens 114. The blue light (B) transmitted through the dichroic mirror 105 is incident on the liquid crystal light valve 123 via a light guide system including three relay lenses 111, 112, and 113 and the two reflection mirrors 107 and 108.

The transmission type liquid crystal light valves 121, 122, and 123 as light modulation elements are disposed so as to be opposite to each color light incident surface of the cross dichroic prism 116. The color light which is incident on the liquid crystal light valves 121, 122, and 123 is modulated based on video information (video signal), and is emitted toward the cross dichroic prism 116.

The cross dichroic prism 116 is formed by bonding four right-angle prisms. Inside of the cross dichroic prism 116, a dielectric multilayer film which reflects the red light and a dielectric multilayer film which reflects the blue light are formed in a “+” shape. Three color light beams are synthesized by the dielectric multilayer films, and thus light beams representing a color image are synthesized. The synthesized light beams are projected onto a screen 130 by the projection lens 117 as a projection optical system, and thus the image is enlarged and displayed.

The liquid crystal light valve 121 is one to which the liquid crystal device 1 according to the embodiment is applied. The liquid crystal light valve 121 is disposed with a gap between a pair of polarization elements, which are disposed on a light incident side and a light emission side of color light in a cross-Nicol manner. The same applies to the other liquid crystal light valves 122 and 123.

With the configuration of the projector 100 according to the present embodiment, even when a plurality of pixels P are disposed with high resolution, the liquid crystal device 1 capable of realizing the high aperture ratio and securing the holding capacitance is provided, and thus it is possible to provide the projector 100 with high quality and high brightness.

The above-described embodiments have been presented to explain one aspect according to the invention only, and various modification and application may be made within a scope of the invention. As a modification example, for example, the following can be considered.

### Modification Example 1

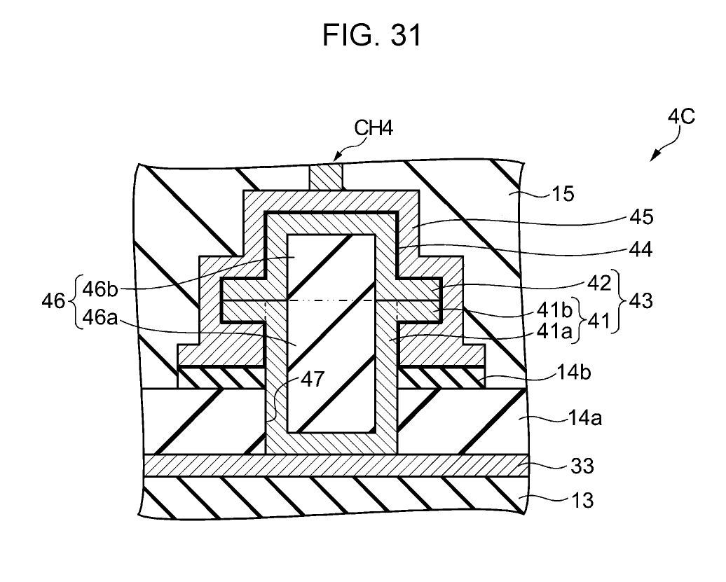

Although the liquid crystal device 1 according to the embodiment is configured to include the capacitor 4, 4A, or 4B including the insulator 46 in which the width of the second portion 46b is wider than the width of the first portion 46a, the invention is not limited to such a form. The capacitor may include an insulator 46 in which the width of the second portion 46b is the same as the width of the first portion 46a. FIG. 31 is a schematic sectional view illustrating a structure of the capacitor according to a modification example 1.

As illustrated in FIG. 31, in the insulator 46 included in the capacitor 4C according to the modification example 1, the width of the second portion 46b is the same as the width of the first portion 46a. Even in such a configuration, an area of the lower electrode 43 opposite to the upper electrode 45 can be increased by an area of a portion of the first capacitor electrode 41 including the flange portion 41b, and thus the same effects as those in the embodiment can be obtained.

### Modification Example 2

In the liquid crystal device 1 according to the embodiment, although the capacitor 4, 4A, or 4B has the configuration in which the sectional shape of the portion extending along the X direction is the same as the sectional shape of the portion extending along the Y direction, the invention is not limited to such a form. In the capacitor, the sectional shape of the portion extending along the X direction and the sectional shape of the portion extending along the Y direction may be different from each other. More specifically, for example, the portion extending along the X direction may have the sectional shape of the capacitor 4, and the portion extending along the Y direction may have the sectional shape of the capacitor 4A. In this way, the above embodiments may be combined with each other.

### Modification Example 3

The electronic apparatus to which the liquid crystal device 1 according to the above embodiment can be applied is not limited to the projector 100. The liquid crystal device 1 can be appropriately used as a display unit of an information terminal apparatus such as a projection type head up display (HUD) or a direct view type head mount display (HMD), an electronic book, a personal computer, a digital still camera, a liquid crystal television, a view finder type video recorder or a monitor direct view type video recorder, a car navigation system, an electronic organizer, or a POS.

The entire disclosure of Japanese Patent Application No. 2017-031825, filed Feb. 23, 2017 is expressly incorporated by reference herein.

What is claimed is:

1. An electrooptical device comprising:
a substrate;
an insulating layer disposed on the substrate;
a groove provided on the insulating layer for each pixel; and
a capacitor provided on the groove,
wherein the capacitor includes
a first capacitor electrode that includes a recess-shaped portion disposed in the groove and a flange portion extending outside the recess-shaped portion from an upper end of the recess-shaped portion along a planar direction of the substrate,
an insulator that includes a first portion disposed in the recess-shaped portion and a second portion protruding in a projection shape from the upper end of the recess-shaped portion along a thickness direction of the substrate,
a second capacitor electrode that is disposed so as to cover the second portion of the insulator and to overlap with the first capacitor electrode in plan view and is connected to the flange portion,
a capacitor insulating film that covers an outer surface of the second capacitor electrode and an outer surface of a portion of the first capacitor electrode including the flange portion, and
a third capacitor electrode that covers the second capacitor electrode and the portion of the first capacitor electrode including the flange portion by interposing the capacitor insulating film.

2. The electrooptical device according to claim 1,
wherein the second portion of the insulator overlaps with a portion of the flange portion of the first capacitor electrode in plan view.

3. The electrooptical device according to claim 1,
wherein the insulator includes a recess portion which is recessed from the second portion to the first portion, and
wherein the second capacitor electrode is also disposed in the recess portion of the insulator.

4. The electrooptical device according to claim 1,
wherein the recess-shaped portion includes a bottom portion disposed in the groove and a portion on the upper end side that is disposed above the insulating layer, and
wherein the portion of the first capacitor electrode includes the portion on the upper end side of the recess-shaped portion and the flange portion.

5. The electrooptical device according to claim 4, further comprising:
an electrode that is disposed between the substrate and the capacitor and is brought into contact with the bottom portion of the recess-shaped portion.

6. The electrooptical device according to claim 1, further comprising:
a switching element disposed between the substrate and the capacitor; and
a light shielding layer disposed between the substrate and the switching element so as to overlap with the switching element in plan view,
wherein the capacitor is disposed so as to overlap with the light shielding layer in plan view.

7. The electrooptical device according to claim 1,
wherein the capacitor includes an intersection portion in which a portion extending along a first direction of the planar direction and a portion extending along a second direction of the planar direction that intersects with the first direction are connected to each other.

8. An electro optical device comprising:
a substrate;
a capacitor disposed on the substrate;
wherein the capacitor includes
a first capacitor, a second capacitor arranged along the shape of the first capacitor, and a capacitor insulating film disposed between the first capacitor and the second capacitor,
wherein the first capacitor includes
a first portion having an upper surface, a second portion extending downward from an end portion of the first portion, a third portion extending inwardly from a side end portion of the second portion, and a fourth portion extending downward from the third portion extending.

9. An electronic apparatus comprising:
the electrooptical device according to claim 1.

10. An electronic apparatus comprising:
the electrooptical device according to claim 2.

11. An electronic apparatus comprising:
the electrooptical device according to claim 3.

12. An electronic apparatus comprising:
the electrooptical device according to claim 4.

13. An electronic apparatus comprising:
the electrooptical device according to claim 5.

14. An electronic apparatus comprising:
the electrooptical device according to claim 6.

15. An electronic apparatus comprising:
the electrooptical device according to claim 7.

16. An electronic apparatus comprising:
the electrooptical device according to claim 8.

17. A manufacturing method of an electrooptical device, the method comprising:
forming an insulating layer stack in an order of a first insulating layer, a second insulating layer, and a third insulating layer which is inferior to the second insulating layer in etching resistance on a substrate;
forming a groove extending from the third insulating layer to the first insulating layer by anisotropic etching;
forming a first capacitor electrode film which covers a front surface of the third insulating layer and includes a recess-shaped portion in the groove;
forming a fourth insulating layer in the recess-shaped portion and on the first capacitor electrode film;
forming an insulator that includes a first portion disposed in the recess-shaped portion and a second portion protruding in a projection shape from an upper end of the recess-shaped portion above the first capacitor electrode film, by removing a portion of the fourth insulating layer by anisotropic etching;
forming a second capacitor electrode film so as to cover the second portion of the insulator and the first capacitor electrode film which is exposed in the insulator formation;
forming a second capacitor electrode by removing the second capacitor electrode film by anisotropic etching except for a portion of the second capacitor electrode film that covers the second portion of the insulator and is brought into contact with the first capacitor electrode film;
forming a first capacitor electrode by removing the first capacitor electrode film by anisotropic etching except for a portion of the first capacitor electrode film that overlaps with the second capacitor electrode in plan view;
removing the third insulating layer by isotropic etching;
forming a capacitor insulating film which covers an outer surface of the second capacitor electrode and an outer surface of a portion of the first capacitor electrode that is positioned above the second insulating layer;
forming a third capacitor electrode film so as to cover the capacitor insulating film; and
forming a third capacitor electrode by removing the third capacitor electrode film by anisotropic etching except for a portion of the third capacitor electrode film which covers the second capacitor electrode and the portion of the first capacitor electrode that is positioned above the second insulating layer by interposing the capacitor insulating film.
